(19) United States
(12) Patent Application Publication
(10) Pub. No.: US 2011/0189835 A1
(43) Pub. Date: Aug. 4, 2011

(54) FILM FOR MANUFACTURING SEMICONDUCTOR DEVICE AND METHOD OF MANUFACTURING SEMICONDUCTOR DEVICE

(76) Inventors: Yuki Sugo, Osaka (JP); Shumpei Tanaka, Osaka (JP); Takeshi Matsumura, Osaka (JP); Yasushi Inoue, Osaka (JP)

(21) Appl. No.: 13/017,218

(22) Filed: Jan. 31, 2011

(30) Foreign Application Priority Data
Feb. 1, 2010 (JP) 2010-020580
Dec. 3, 2010 (JP) 2010-270438

(51) Int. Cl. H01L 21/78; B32B 7/12

(52) U.S. Cl. 438/464; 428/345; 428/334; 257/E21.599

(57) ABSTRACT

There is provided a new film for manufacturing a semiconductor device that is superior to prevent contamination of a semiconductor chip having an excellent balance of holding power during dicing a semiconductor wafer even where the semiconductor wafer is thin, peeling property when peeling the semiconductor chip that is obtained by dicing together with its adhesive layer, and low contamination property in which there is no attachment of cutting debris to the semiconductor chip. A film for manufacturing a semiconductor device that is used when manufacturing a semiconductor device has a base layer, a first pressure-sensitive adhesive layer that is provided on the base layer, a radiation curing-type second pressure-sensitive adhesive layer that is provided on the first pressure-sensitive adhesive layer and cured by radiation irradiation in advance, and an adhesive layer that is provided on the second pressure-sensitive adhesive layer.

### BACKGROUND OF THE INVENTION

1. Field of the Invention

The present invention relates to a film for manufacturing a semiconductor device that is used in manufacturing of a semiconductor device and, more specifically, to a film for manufacturing a semiconductor device that is used in a series of steps, etc. after a semiconductor chip is formed by dicing a semiconductor wafer until the semiconductor chip is adhered and fixed onto an adherend. The present invention also relates to a method of manufacturing a semiconductor device using the film for manufacturing a semiconductor device.

2. Description of the Related Art

A semiconductor wafer with a circuit pattern has its thickness adjusted by backside polishing as necessary and then is diced into semiconductor chips (a dicing step). In the dicing step, the semiconductor wafer is generally washed at an appropriate liquid pressure (normally, about 2 kg/cm²) to remove a cut layer. Then, the semiconductor chips are die-bonded on an adherend such as a lead frame with an adhesive. In this step, the adhesive is applied onto the lead frame and the semiconductor chip. However, in this method, it is difficult to make a uniform adhesive layer, and a special apparatus and a long time are required for the application of the adhesive. Accordingly, a dicing die-bonding film has been proposed that adheres and holds a semiconductor wafer in the dicing step and that provides an adhesive layer for fixing a chip necessary for die bonding (for example, refer to Japanese Patent Application Laid-Open No. 60-57642).

The dicing die-bonding film described in Japanese Patent Application Laid-Open No. 60-57642 has an adhesive peeling layer (a pressure-sensitive adhesive layer) and a conductive adhesive layer provided on a support film (a base layer). That is, a semiconductor wafer is diced while being held by the adhesive layer, semiconductor chips are peeled together with the adhesive layer by stretching the support film, the chips are individually collected, and the chips are fixed to an adherend such as a lead frame through the adhesive layer.

The adhesive layer of the dicing die-bonding film of this type is desired to have a good holding power to the semiconductor wafer so that dicing difficulties, dimensional errors, and the like do not occur and a good peeling property so that the semiconductor chip after dicing can be peeled together with the adhesive layer from a support base. The pressure-sensitive adhesive layer of the dicing die-bonding film is desired to have a good holding power to a ring frame, adhesion to the adhesive layer to prevent scattering of the semiconductor chips that are individualized during dicing, and a low contamination property so that cutting debris that is generated during dicing do not attach to the semiconductor chip with an adhesive layer.

However, since it is not easy to exhibit these characteristics with good balance, and especially in recent years, the thickness of a semiconductor chip has been made smaller and its surface area has been made larger for the purpose of obtaining a larger capacity, it has been more difficult to satisfy the various requirements for the base layer and the pressure-sensitive adhesive layer. That is, for the various demand characteristics, a conventional dicing die-bonding film cannot exhibit the above-described characteristics with good balance because it does not fulfill each of the different functions.

Various modification methods have been proposed to solve the above problems. For example, a pressure-sensitive adhesive tape for dicing has been proposed in Japanese Patent Application Laid-Open No. 2006-203000 in which a dicing sheet, a peeling film, a die-attach film, and a release film are sequentially laminated. In this pressure-sensitive adhesive tape for dicing, the die-attach film can be easily peeled together with a semiconductor chip during pickup of the semiconductor chip by providing a new peeling film on the dicing sheet and by making the peeling power between the peeling film and the die-attach film be smaller than that between the peeling film and the dicing sheet. Further, the dicing frame (dicing ring) is securely fixed because it is pasted on the dicing sheet. That is, the pressure-sensitive adhesive tape for dicing described in Japanese Patent Application Laid-Open No. 2006-203000 has a structure in which the desired performance of the dicing die-bonding film, that is, functions of tackiness during dicing and the peeling property during pickup, are separated from each other by providing a peeling film between the dicing sheet and the die-attach film.

However, even with the pressure-sensitive adhesive tape for dicing described in Japanese Patent Application Laid-Open No. 2006-203000, the cutting debris generated from the dicing sheet during dicing the semiconductor wafer attach to the side face of the semiconductor chip, etc. as burrs and whiskers. Accordingly, there is a problem that the yield of manufacturing a semiconductor device decreases.

### SUMMARY OF THE INVENTION

The present invention has been made in view of the above-described problems, and an object thereof is to provide a new film for manufacturing a semiconductor device that is superior to prevent contamination of a semiconductor chip having an excellent balance of holding power during dicing of a semiconductor wafer even when the semiconductor wafer is thin, peeling property when peeling the semiconductor chip that is obtained by dicing together with its adhesive layer, and low contamination property in which there is no attachment of cutting debris to the semiconductor chip, and a method of manufacturing a semiconductor device.

The present inventors investigated a film for manufacturing a semiconductor device and a method of manufacturing a semiconductor device to solve the above-described conventional problems. As a result, it was found that the object can be achieved by adopting the following configuration, and the present invention was completed.

To achieve the above-described object, the present invention provides a film for manufacturing a semiconductor device used when manufacturing a semiconductor device, having a base layer, a first pressure-sensitive adhesive layer that is provided on the base layer, a radiation curing-type second pressure-sensitive adhesive layer that is provided on the first pressure-sensitive adhesive layer and cured by radiation irradiation in advance, and an adhesive layer that is provided on the second pressure-sensitive adhesive layer.

The conventional dicing die-bonding film that is used in manufacturing of a semiconductor device generally has a structure in which the pressure-sensitive adhesive layer and the adhesive layer are sequentially laminated on the base layer. The pressure-sensitive adhesive layer is desired to have adherability that can prevent chip fly of a semiconductor chip during dicing of the semiconductor wafer and a peeling property so that the chips can be easily peeled from the adhesive layer during pickup of the semiconductor chip. That is, the pressure-sensitive adhesive layer has been desired to have functions that are contrary to each other in the dicing step and the pickup step.

On the other hand, in the present invention, separation of functions of the adherability during dicing and the peeling property during pickup that has been desired for the pressure-sensitive adhesive layer of the conventional dicing die-bonding film is made possible by sequentially providing the first pressure-sensitive adhesive layer and the second pressure-sensitive adhesive layer on the base layer as the above-described configuration. That is, because the first pressure-sensitive adhesive layer is fixed by adhering the second pressure-sensitive adhesive layer, chip fly of the semiconductor chip can be prevented when dicing the semiconductor wafer that is pasted on the adhesive layer. Because the peeling property during pickup is not required for the first pressure-sensitive adhesive layer, the structure in which provided on the base layer exhibits a function as a sort of a carrier tape. On the other hand, because the second pressure-sensitive adhesive layer is cured by radiation irradiation in advance, it exhibits a good peeling property to the adhesive layer. Accordingly, the pickup of the semiconductor chip can be performed satisfactorily. Further, a step of irradiating with radiation before pickup can be omitted.

In the conventional dicing die-bonding film, dicing of the semiconductor wafer is performed until the cut depth of a dicing blade, etc. reaches to the pressure-sensitive adhesive layer or the base layer. However, there is a case that a portion of the pressure-sensitive adhesive layer becomes burrs or whiskers at the cut surface and attaches to the boundary of the pressure-sensitive adhesive layer and the adhesive layer when the dicing is performed into a portion of the pressure-sensitive adhesive layer. Further, there is a case that string-like cutting debris is generated and contaminates the semiconductor chip when the dicing is performed into the base layer. However, because the dicing die-bonding film in the present invention has a structure in which the first pressure-sensitive adhesive layer and the second pressure-sensitive adhesive layer are laminated on the base layer, there is no necessity of performing dicing so that the cut depth of the dicing blade, etc. reaches to the first pressure-sensitive adhesive layer, and the dicing can be stopped at the second pressure-sensitive adhesive layer. Further, because the second pressure-sensitive adhesive layer is cured by radiation irradiation in advance, it can be suppressed that a portion of the second pressure-sensitive adhesive layer becomes burrs at the cut surface and attaches to the boundary of the second pressure-sensitive adhesive layer and the adhesive layer. As a result, a semiconductor chip with an adhesive layer can be picked up satisfactorily. Because it is not necessary to perform dicing that reaches to the base layer, the string-like cutting debris is not generated. Accordingly, a low contamination property of the semiconductor chip can be achieved in the film for manufacturing a semiconductor device of the present invention.

In the above-described configuration, the second pressure-sensitive adhesive layer and the adhesive layer are provided so as to fit at least inside of a pasting portion of the dicing ring in the first pressure-sensitive adhesive layer, the plane shape of the adhesive layer is larger than that of the second pressure-sensitive adhesive layer, the adhesive layer is provided so as to cover the entire surface of the second pressure-sensitive adhesive layer, and the peripheral edge part in the adhesive layer that is not located on the second pressure-sensitive adhesive layer is preferably provided on the first pressure-sensitive adhesive layer.

According to the above-described configuration, because the dicing ring can be pasted onto the first pressure-sensitive adhesive layer where the peeling property during pickup is not required, the dicing ring can be securely fixed during dicing. Attachment of the adhesive can be suppressed when peeling the dicing ring after use, compared to the case that the dicing ring is pasted on the adhesive layer. The plane shape of the adhesive layer is larger than that of the second pressure-sensitive adhesive layer, and the adhesive layer is provided so as to cover the entire surface of the second pressure-sensitive adhesive layer. The peripheral edge part of the adhesive layer is provided not on the second pressure-sensitive adhesive layer but on the first pressure-sensitive adhesive layer. Because the adhesive layer is firmly adhered on the first pressure-sensitive adhesive layer, the adhesive layer can be prevented from peeling and coming off from the second pressure-sensitive adhesive layer during dicing.

In the above-described configuration, bending stiffness S calculated by E×I of a structure in which the base layer, the first pressure-sensitive adhesive layer, and the second pressure-sensitive adhesive layer are laminated (for example, a dicing film) is preferably in a range of 5.0×10⁴ to 7.0×10⁵ (wherein I is a second moment of area represented with b×T³/12, b is 10 (mm) that is the width of a test piece of the structure, T is the thickness (mm) of the structure, and E is a tensile storage modulus (Pa) at 25° C. of the structure). By making the bending stiffness S be 5.0×10⁴ or more, the stiffness of the structure can be maintained, and pasting of a wafer without any wrinkles becomes possible. On the other hand, by making the bending stiffness S be 7.0×10⁵ or less, the structure bends properly during pickup, and a stable pickup can be performed.

In the above-described configuration, peeling strength X between the second adhesive layer and the adhesive layer is preferably in a range of 0.01 to 0.2 N/20 mm. By making the peeling strength X between the second pressure-sensitive adhesive layer and the adhesive layer be 0.01 N/20 mm or more, peeling is prevented between them during dicing of a semiconductor wafer, and the generation of chip fly of the semiconductor chip can be prevented. On the other hand, by making the peeling strength X be 0.2N/20 mm or less, the semiconductor chip can be picked up satisfactorily even when the step of irradiating with radiation is omitted.

In the above-described configuration, the peeling strength Y between the first pressure-sensitive adhesive layer and the second pressure-sensitive adhesive layer is preferably in a range of 0.2 to 10 N/20 mm. By making the peeling strength Y between the first pressure-sensitive adhesive layer and the second pressure-sensitive adhesive layer be 0.2 N/20 mm or more, the semiconductor wafer and the semiconductor chip can be securely fixed during dicing. By making the peeling strength Y be 10 N/20 mm or less, the second pressure-sensitive adhesive layer can be peeled from the first pressure-sensitive adhesive layer, and the laminated film can be reused as a carrier tape including the base layer and the first pressure-sensitive adhesive layer.

In the above-described configuration, the ratio (Y/X) of the peeling strength Y between the first pressure-sensitive adhesive layer and the second pressure-sensitive adhesive layer to the peeling strength X between the second pressure-sensitive adhesive layer and the adhesive layer is preferably in a range of 3 to 500. By making the ratio (Y/X) of the peeling strength Y to the peeling strength X be 3 or more, the peeling interface during pickup of the semiconductor chip can be made to be the boundary of the second pressure-sensitive adhesive layer and the adhesive layer. On the other hand, by making the ratio (Y/X) be 500 or less, chip fly and releasing of the adhesive layer during dicing are suppressed, and stable dicing can be performed.

In the above-described configuration, the thickness of the second pressure-sensitive adhesive layer is preferably in a range of 10 to 100 μm. By making the thickness of the second pressure-sensitive adhesive layer be 10 μm or more, the cut depth of the dicing blade, etc. can be prevented from reaching to the first pressure-sensitive adhesive layer during dicing. On the other hand, by making the thickness of the second pressure-sensitive adhesive layer be 100 μm or less, a stable pickup of the semiconductor chips can be possible.

In the above-described configuration, the peeling strength between the first pressure-sensitive adhesive layer and a SUS304-BA plate is preferably in a range of 0.2 to 11 N/20 mm. By making the peeling strength between the first pressure-sensitive adhesive layer and the SUS304-BA plate be 0.2 N/20 mm or more, the dicing ring can be securely adhered and fixed, and the dicing can be performed well. On the other hand, by making the peeling strength be 11 N/20 mm or less, generation of adhesive residue on the dicing ring can be reduced when peeling the dicing ring after use from the first pressure-sensitive adhesive layer.

In the above-described configuration, the second pressure-sensitive adhesive layer is preferably formed on the first pressure-sensitive adhesive layer after a precursor of the second pressure-sensitive adhesive layer is cured by radiation irradiation.

In the above-described configuration, the second pressure-sensitive adhesive layer is preferably formed by being cured by radiation irradiation after the precursor of the second pressure-sensitive adhesive layer is provided on the first pressure-sensitive adhesive layer.

In the above-described configuration, the adhesive layer is preferably formed on the second pressure-sensitive adhesive layer that is cured by radiation irradiation in advance.

In the above-described configuration, the adhesive layer is preferably provided on the precursor of the second pressure-sensitive adhesive layer before being cured by radiation irradiation.

In the above-described configuration, the adhesive layer is preferably formed of at least an epoxy resin, a phenol resin, and an acrylic resin.

In the above-described configuration, the glass transition temperature of the acrylic resin is preferably in a range of −30 to 10° C. By making the glass transition temperature of the acrylic resin be −30° C. or more, the storage modulus of the adhesive layer at high temperature (for example, 100 to 200° C.) can be maintained. On the other hand, by making the glass transition temperature be 10° C. or less, good adhesion and stickiness to a semiconductor wafer can be exhibited.

In the above-described configuration, the second pressure-sensitive adhesive layer is preferably formed of at least an acrylic polymer.

To achieve the above-described object, the present invention provides a method of manufacturing a semiconductor device using the film for manufacturing a semiconductor device, including at least the steps of adhering a semiconductor wafer onto the adhesive layer of the film for manufacturing a semiconductor device by pressing, forming a semiconductor chip by dicing the semiconductor wafer together with the adhesive layer, in which the cut depth of dicing is stopped at the second pressure-sensitive adhesive layer, and peeling the semiconductor chip from the second pressure-sensitive adhesive layer together with the adhesive layer, wherein the second pressure-sensitive adhesive layer is not irradiated with radiation from the step of adhering a semiconductor wafer by pressing until the step of peeling a semiconductor chip.

In the above-described method, a semiconductor device is manufactured using a film for manufacturing a semiconductor device having a structure in which a first pressure-sensitive adhesive layer, a second pressure-sensitive adhesive layer, and an adhesive layer are sequentially laminated on a base layer. Because the first pressure-sensitive adhesive layer is fixed by adhering the second pressure-sensitive adhesive layer, chip fly of the semiconductor chip can be prevented when dicing the semiconductor wafer. In addition, because the cut depth of dicing is stopped at the second pressure-sensitive adhesive layer during dicing of the semiconductor wafer, the cutting debris that is generated when dicing the base layer is prevented from becoming burrs and whiskers and attaching to the semiconductor chip. Further, because the second pressure-sensitive adhesive layer is cured by radiation irradiation in advance, it can be suppressed that a portion of the second pressure-sensitive adhesive layer becomes burrs and whiskers at the cut surface and attaches to the boundary of the second pressure-sensitive adhesive layer and the adhesive layer. As a result, a semiconductor chip with an adhesive layer can be picked up satisfactorily.

Because the second pressure-sensitive adhesive layer is cured by radiation irradiation in advance, it exhibits a good peeling property to the adhesive layer. Accordingly, the semiconductor chip can be picked up satisfactorily. Further, the number of steps can be reduced because it is not necessary to irradiate the second pressure-sensitive adhesive layer with radiation from the step of adhering a semiconductor wafer by pressing until the step of peeling a semiconductor chip.

The present invention realizes the effects described below by the means discussed above. That is, the film for manufacturing a semiconductor device of the present invention adopts a configuration in which the first pressure-sensitive adhesive layer, the second pressure-sensitive adhesive layer, and the adhesive layer are sequentially provided on the base layer, provides a function of securely adhering and fixing the second pressure-sensitive adhesive layer to the first pressure-sensitive adhesive layer, and provides a good peeling property to the adhesive layer by being cured by radiation irradiation in advance to the second pressure-sensitive adhesive layer. That is, the adherability during dicing and the peeling property during pickup that have been desired for the pressure-sensitive adhesive layer of the conventional dicing die-bonding film are functionally separated. As a result, a film for manufacturing a semiconductor device can be obtained having a holding power during dicing a semiconductor wafer and an excellent peeling property during pickup of a semiconductor chip even in the case that the thickness of semiconductor chip is made smaller and the size of the semiconductor chip is made larger. Because it is not necessary to cut through to the base layer and the cut depth can be stopped at the second pressure-sensitive adhesive layer during dicing, the generation of the cutting debris is suppressed, and the attachment of the cutting debris to the semiconductor chip can be reduced. That is, the present invention can provide a film for manufacturing a semiconductor device having an excellent low contamination property. Further, according to a method of manufacturing a semiconductor device of the present invention, the yield can be improved by manufacturing a semiconductor device using the film for manufacturing a semiconductor device.

### BRIEF DESCRIPTION OF THE DRAWINGS

FIG. 1 is a schematic sectional view showing a film for manufacturing a semiconductor device according to an embodiment of the present invention;

FIG. 2 is a plan view of the film for manufacturing a semiconductor device when viewed from a separator side; and

FIGS. 3A to 3C are explanatory views of a method of manufacturing a semiconductor device using the film for manufacturing a semiconductor device, FIG. 3A shows a step of pasting a semiconductor wafer onto the film for manufacturing a semiconductor device, FIG. 3B shows a step of dicing the semiconductor wafer, and FIG. 3C shows a step of picking up a semiconductor chip.

### DETAILED DESCRIPTION OF THE PREFERRED EMBODIMENTS

### (Film for Manufacturing a Semiconductor Device)

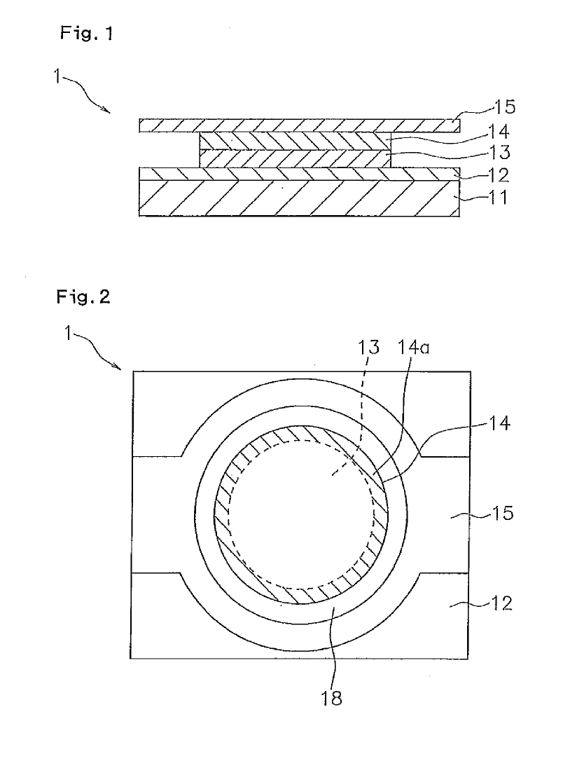

A film for manufacturing a semiconductor device according to the present embodiment is described below with reference to FIGS. 1 and 2. FIG. 1 is a schematic sectional view showing a film for manufacturing a semiconductor device according to an embodiment of the present invention. FIG. 2 is a plan view of the film for manufacturing a semiconductor device when viewed from a separator side.

As shown in FIG. 1, a film 1 for manufacturing a semiconductor device has a structure in which at least a first pressure-sensitive adhesive layer 12, a second pressure-sensitive adhesive layer 13, and an adhesive layer 14 are sequentially provided on a base layer 11. As shown in FIG. 1, the film 1 for manufacturing a semiconductor device according to the present invention may be provided with a separator 15 for protecting the surfaces of the first pressure-sensitive adhesive layer 12 and the adhesive layer 14. Further, the base layer 11 and the first pressure-sensitive adhesive layer 12 are used to adhere and fix the second pressure-sensitive adhesive layer 13 and a dicing ring (described later), and function as a carrier tape.

### [Base Layer]

Constituent materials of the base layer 11 are not especially limited and include, for example, polyolefin such as low density polyethylene, linear polyethylene, medium density polyethylene, high density polyethylene, very low density polyethylene, random copolymerized polypropylene, block copolymerized polypropylene, homopolypropylene, polybutene, and polymethylpentene, polyester such as an ethylene-vinylacetate copolymer, an ethylene-propylene copolymer, an ionomer resin, an ethylene-(meth)acrylic acid copolymer, an ethylene-(meth)acrylate (random or alternating) copolymer, an ethylene-butene copolymer, an ethylene-hexene copolymer, polyurethane, polyethylene terephthalate, and polyethylene naphthalate, polycarbonate, polyimide, polyetheretherketone, polyimide, polyetherimide, polyamide, wholly aromatic polyamide, polyphenylsulfide, aramid paper, glass, glass cloth, a fluorine resin, polyvinyl chloride, polyvinylidene chloride, a cellulose resin, a silicone resin, and a plastic film formed from mixtures thereof. Further, the material of the base layer 11 includes a polymer such as a cross-linked body of the above resins. The above plastic film may be also used unstreched, or may be also used on which a monoaxial or a biaxial stretching treatment is performed depending on necessity.

A known surface treatment such as a chemical or physical treatment such as a chromate treatment, ozone exposure, flame exposure, high voltage electric exposure, and an ionized ultraviolet treatment, and a coating treatment by an undercoating agent (for example, a tacky substance described later) can be performed on the surface of t the base layer 11 in order to improve adhesiveness, holding properties, etc. with the adjacent layer.

The same types or different types of materials can be appropriately selected and used for the constituent materials of the base layer 11. Materials of which a few types are blended can be used as necessary. As the base layer 11, in order to impart antistatic properties, a film can be used where a vapor deposition layer made of a conductive vapor deposition layer made of metals, alloys, or their oxides and having a thickness of about 30 to 500 Å is provided on the above-described plastic film. A laminated body in which the above-described films are pasted to each other or to other films can also be used. Further, the base layer 11 may be a single layer or a multi-layered film where two layers or more of the films made of the above-described materials are laminated.

The thickness of the base layer 11 is not especially limited as long as the layer does not rupture during the expansion described later, and it is appropriately set. In general, its thickness is preferably in a range of 5 to 200 μm.

### [First Pressure-Sensitive Adhesive Layer]

The first pressure-sensitive adhesive layer 12 is provided on the base layer 11 and is a layer used to adhere and fix the second pressure-sensitive adhesive layer 13 and the dicing ring. In FIG. 1, the first pressure-sensitive adhesive layer 12 is provided on the entire surface of the rectangular base layer 11, and its plane shape is rectangular. However, the plane shape may be circular, etc. Further, because the peeling is performed between the second pressure-sensitive adhesive layer 13 and the adhesive layer 14 when picking up the semiconductor chip as described later, a peeling property during pickup is not especially required for the first pressure-sensitive adhesive layer 12. That is, the basic performance of the first pressure-sensitive adhesive layer 12 is in adherability. Therefore, the constituent materials of the first pressure-sensitive adhesive layer 12 are not especially limited, and conventionally known materials can be adopted.

A generally used pressure-sensitive adhesive can be used as the pressure-sensitive adhesive that constitutes the first pressure-sensitive adhesive layer 12. Specific examples thereof are various pressure-sensitive adhesives such as an acrylic pressure-sensitive adhesive, a rubber pressure-sensitive adhesive, a silicone pressure-sensitive adhesive, and polyvinylether. Among those, a (meth)acrylic pressure-sensitive adhesive having a (meth)acrylic polymer as a base polymer is preferable in terms of tackiness to the semiconductor wafer and a semiconductor package to be cut, cleaning property of a semiconductor wafer after peeling, etc. by ultrapure water and an organic solvent such as alcohol, etc. Moreover, (meth) means to include both an acrylic polymer and a methacrylic polymer in the case of a (meth)acrylic polymer, for example. This also applies to the compounds exemplified below.

Specific examples of the acryl polymers include an acryl polymer in which acrylate is used as a main monomer component. Examples of the acrylate include alkyl acrylate (for example, a straight chain or branched chain alkyl ester having 1 to 30 carbon atoms, and particularly 4 to 18 carbon atoms in the alkyl group such as methylester, ethylester, propylester, isopropylester, butylester, isobutylester, sec-butylester, t-butylester, pentylester, isopentylester, hexylester, heptylester, octylester, 2-ethylhexylester, isooctylester, nonylester, decylester, isodecylester, undecylester, dodecylester, tridecylester, tetradecylester, hexadecylester, octadecylester, and eicosylester), cycloalkyl acrylate (for example, cyclopentylester, cyclohexylester, etc.), a (meth)acrylic polymer using one type or two types or more of hydroxyalkyl (meth)acrylate (such as hydroxyethyl ester, hydroxybutyl ester, and hydroxyhexyl ester), glycidyl (meth)acrylate, (meth)acrylate, itaconic acid, maleic anhydride, (meth) acrylamide, N-hydroxymethylamide (meth)acrylate, alkylaminoalkyl (meth)acrylate (such as dimethylaminoethyl methacrylate and t-butylaminoethyl methacrylate), vinylacetate, and styrene as a monomer component. These monomers may be used alone or two or more types may be used in combination.

The (meth) acrylic polymer may include a unit corresponding to other monomer components that can be copolymerized with the alkyl (meth)acrylate or cycloalkyl ester as necessary for reforming cohesive strength, tackiness, etc. Examples of such a monomer component include carboxyl-containing monomers such as acrylic acid, methacrylic acid, carboxyethyl(meth)acrylate, carboxypentyl (meth)acrylate, itaconic acid, maleic acid, fumaric acid, and crotonic acid; acid anhydride monomers such as maleic anhydride, and itaconic anhydride; hydroxyl-containing monomers such as 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate, and (4-hydroxylmethylcyclohexyl)methyl (meth)acrylate; sulfonic acid group containing monomers such as styrenesulfonic acid, allylsulfonic acid, 2-(meth)acrylamide-2-methylpropanesulfonic acid, (meth) acrylamidepropanesulfonic acid, sulfopropyl (meth)acrylate, and (meth) acryloyloxynaphthalenesulfonic acid; phosphoric acid group containing monomers such as 2-hydroxyethylacryloyl phosphate; acrylamide; and acrylonitrile. These copolymerizable monomer components may be used alone or in combination of two or more thereof. The used amount of these copolymerizable monomers is preferably 30% by weight or less to the total monomer components, and more preferably 15% by weight or less.

The (meth)acrylate polymer can include a multifunctional monomer, etc. as a monomer component for copolymerization as necessary for crosslinking. Because a self holding property of the pressure-sensitive adhesive layer is improved by crosslinking the base polymer, large deformation of the pressure-sensitive adhesive sheet can be prevented, and a plate state of the first pressure-sensitive adhesive layer 12 can be easily maintained.

Such multifunctional monomers include hexane diol di(meth)acrylate, (poly)ethylene glycol di(meth)acrylate, (poly)propylene glycol di(meth)acrylate, neopentyl glycol di(meth)acrylate, pentaerythritol di(meth)acrylate, trimethylol propane tri(meth)acrylate, pentaerythritol tri(meth)acrylate, dipentaerythritol hexa(meth)acrylate, epoxy (meth)acrylate, polyester (meth)acrylate, urethane (meth)acrylate etc. These multifunctional monomers can also be used as a mixture of one or more thereof. From the viewpoint of adhesiveness etc., the use amount of the multifunctional monomer is preferably 30 wt % or less based on the whole monomer components.

The (meth) acrylic polymer can be obtained by polymerizing a single monomer or a mixture of two types or more of monomers. The polymerization can be performed with any method of solution polymerization, emulsion polymerization, bulk polymerization, suspension polymerization, photopolymerization, etc. Particularly, when polymerizing by irradiating with radiation such as an ultraviolet ray and an electron beam, the (meth) acrylic polymer is preferably synthesized by photopolymerization by casting a liquid composition that can be obtained by compounding the monomer component and a photopolymerization initiator into a urethane (meth)acrylate oligomer.

The number average molecular weight of the urethane (meth) acrylate oligomer is about 500 to 100,000, preferably 1000 to 30,000, and it is a bifunctional compound having esterdiol as a main skeleton. Examples of the monomer component include morpholine (meth)acrylate, isobornyl (meth)acrylate, dicyclopentanyl (meth)acrylate, dicyclopentenyl (meth)acrylate, and methoxylated cyclododecatriene (meth)acrylate. The mixing ratio of the urethane (meth)acrylate oligomer to the monomer component is preferably 95 to 5:5 to 95 (% by weight), and more preferably 50 to 70:50 to 30 (% by weight). When the content of the urethane (meth)acrylate oligomer is large, the viscosity of the liquid composition becomes high and the polymerization tends to be difficult.

The weight average molecular weight of the (meth)acrylic polymer is preferably about 100,000 to 1,000,000, and more preferably about 150,000 to 900,000 from the viewpoint of the cohesive strength.

An external crosslinking agent can be appropriately adopted in the pressure-sensitive adhesive to increase the number average molecular weight of the (meth)acrylic polymer that is the base polymer, etc. A specific example of a method of external crosslinking is a method of reacting by adding a so-called crosslinking agent such as a polyisocyanate compound, a melamine resin, a urea resin, an epoxy resin, polyamine, and a polymer containing a carboxyl group. When using the external crosslinking agent, the used amount is determined appropriately depending on a balance with the base polymer to be crosslinked and further depending on the usage as a pressure-sensitive adhesive. In general, the external crosslinking agent is preferably compounded at about 1 to 5 parts by weight to 100 parts by weight of the base polymer. Further, additives such as various conventionally known tackifiers and antiaging agents may be used in the pressure-sensitive adhesive besides the above-described components as necessary.

The thickness of the first pressure-sensitive adhesive layer 12 is not especially limited. However, it is preferably in a range of 1 to 30 μm, more preferably in a range of 2 to 25 μm, and especially preferably in a range of 3 to 20 μm from the viewpoint of adherability.

The peeling strength between the first pressure-sensitive adhesive layer 12 and the dicing ring is preferably in a range of 0.2 to 10 N/20 mm, more preferably in a range of 0.3 to 9.5 N/20 mm, and especially preferably in a range of 0.5 to 9 N/20 mm. By making the peeling strength between the first pressure-sensitive adhesive layer 12 and the dicing ring be 0.2 N/20 mm or more, the dicing ring can be securely adhered and fixed, and the dicing can be performed well. On the other hand, by making the peeling strength be 10 N/20 mm or less, the dicing ring after use can be peeled from the first pressure-sensitive adhesive layer while suppressing the generation of adhesive residue.

Moreover, the first pressure-sensitive adhesive layer 12 may contain various additives (such as a coloring agent, a thickener, an extender, a filler, a tackifier, a plasticizer, an antiaging agent, an antioxidant, a surfactant, and a crosslinking agent) in the scope not impairing the effects of the present invention.

### [Second Pressure-Sensitive Adhesive Layer]

The second pressure-sensitive adhesive layer 13 is provided on the first pressure-sensitive adhesive layer 12. The second pressure-sensitive adhesive layer 13 can achieve a function of preventing the cut depth of a dicing blade, etc. from reaching to the base layer 11 and the first pressure-sensitive adhesive layer 12 when dicing a semiconductor wafer. Therefore, the string-like cutting debris that is generated when the base layer 11 is cut can be prevented. As a result, the contamination of the semiconductor chip can be also reduced. Further, the generation of burrs that are generated when the first pressure-sensitive adhesive layer 12 is cut can be prevented.

The second pressure-sensitive adhesive layer 13 is formed from at least a radiation curing-type pressure-sensitive adhesive, and it is cured by radiation irradiation in advance. Accordingly, the adhesive power of the second pressure-sensitive adhesive layer 13 is reduced more than that of a normal pressure-sensitive adhesive layer, and it has an excellent peeling property to the adhesive layer 14. That is, the second pressure-sensitive adhesive layer 13 carries out a function of improving the pickup property of the semiconductor chip. Further, the generation of burrs can be reduced even when a portion of the second pressure-sensitive adhesive layer is cut by the dicing blade during dicing. As a result, there is no obstacle to peeling of the second pressure-sensitive adhesive layer 13 and the adhesive layer 14 that is caused by the pressure-sensitive adhesive attached to the boundary of these layers during pickup. Moreover, examples of the radiation include an x-ray, an ultraviolet ray, and an electron beam.

A region where the second pressure-sensitive adhesive 13 is provided is preferably inside of a dicing ring pasting portion 18 on the first pressure-sensitive adhesive layer 12. As shown in FIG. 2, for example, when the plane shape of the second pressure-sensitive adhesive layer 13 is circular, the diameter thereof is preferably smaller than the inner diameter of the dicing ring. With this, the first pressure-sensitive adhesive layer 12 will be enough to have a performance of securely fixing the second pressure-sensitive adhesive layer 13 and the dicing ring (that is, adherability), and there is no necessity to consider the peeling property during pickup.

The second pressure-sensitive adhesive layer 13 may be provided on the entire surface of the first pressure-sensitive adhesive layer 12. However, the second pressure-sensitive adhesive layer 13 is preferably provided so as to fall into the inside of the dicing ring pasting portion as shown in FIG. 1. With this, the dicing ring can be pasted onto the first pressure-sensitive adhesive layer 12, and it is not necessary to paste onto the second pressure-sensitive adhesive layer 13. With this, adherability to the dicing ring is not desired for the second pressure-sensitive adhesive layer 13 as long as the peeling property during pickup of a semiconductor chip is good.

The second pressure-sensitive adhesive layer 13 is cured by radiation irradiation in advance, and is provided on the first pressure-sensitive adhesive layer 12. When the second pressure-sensitive adhesive layer 13 is cured by irradiation with ultraviolet rays, a crosslinked structure is formed, and with this, the volume of the second pressure-sensitive adhesive layer 13 decreases. Accordingly, when the second pressure-sensitive adhesive layer 13 is cured with radiation after being pasted with the first pressure-sensitive adhesive layer 12, a stress caused by the volume decrease of the second pressure-sensitive adhesive layer 13 is applied to the base layer 11 and the first pressure-sensitive adhesive layer 12, and warping may occur. However, the application of unnecessary stress to the base layer 11, etc. is prevented if it is cured with radiation in advance, and a film for manufacturing a semiconductor device without warping can be obtained.

However, the second pressure-sensitive adhesive layer 13 may be formed by laminating a precursor of the second pressure-sensitive adhesive layer 13 (hereinafter, referred to as a “second pressure-sensitive adhesive layer precursor”) on the first pressure-sensitive adhesive layer 12 and then by curing the second pressure-sensitive adhesive layer precursor by irradiating with radiation. In this case, a lamination state can be maintained in which the adhesion between the first pressure-sensitive adhesive layer 12 and the second pressure-sensitive adhesive layer 13 is not excessively impaired. As a result, the adherability of the second pressure-sensitive adhesive layer 13 can be suppressed from being excessively reduced. Further, the second pressure-sensitive adhesive layer 13 may be formed by laminating the adhesive layer 14 on the second pressure-sensitive adhesive layer precursor and then by curing the second pressure-sensitive adhesive layer precursor by irradiating with radiation.

A radiation curing-type pressure-sensitive adhesive having radiation curable functional groups such as a carbon-carbon double bond and exhibiting adherability can be used without limitation. A specific example of the radiation curing-type pressure-sensitive adhesive is an addition-type radiation curing-type pressure-sensitive adhesive in which a radiation curable monomer component and a radiation curable oligomer component are compounded in a general pressure-sensitive adhesive such as the above-described acrylic pressure-sensitive adhesive, a rubber pressure-sensitive adhesive, a silicone pressure-sensitive adhesive, and a polyvinylether pressure-sensitive adhesive. An acrylic pressure-sensitive adhesive having an acrylic polymer as a base polymer or a polymer main component is preferable as the radiation curing-type pressure-sensitive adhesive in terms of a clean washing property of electronic parts that dislike contamination such as a semiconductor wafer and glass with ultrapure water and an organic solvent such as alcohol.

As the acrylic polymer, with respect to the total amount of the acrylic polymer, an acrylic polymer is preferable having a monomer composition including alkylacrylate represented by CH₂═CHCOOR (wherein, R represents an alkyl group having 6 to 10 carbon atoms, and preferably 8 or 9 carbon atoms) and a monomer containing a hydroxyl group and not including a monomer containing a carboxyl group. When the number of carbon atoms of the alkyl group in the alkylacrylate is less than 6, the peeling power becomes too large, and the pickup property may decrease. On the other hand, when the number of carbon atoms of the alkyl group exceeds 10, tackiness or adhesion to the adhesive layer 14 decreases, and as a result, chip fly may generate during dicing.

Specific examples of alkylacrylate include straight-chain or branched-chain alkylacrylate in which the alkyl group has 6 to 10 carbon atoms (especially 8 or 9 carbon atoms) such as hexylacrylate, heptylacrylate, octylacrylate, isooctylacrylate, 2-ethylhexylacrylate, nonylacrylate, isononylacrylate, decylacrylate, and isodecylacrylate. These monomers can be used alone or two types or more of them can be used together. Further, alkylacrylate in which the alkyl group has 8 or 9 carbon atoms is especially preferable among the alkylacrylates, and more specifically 2-ethylhexylacrylate, isooctylacrylate, and isononylacrylate are the most suitable from the viewpoint of the pickup property.

The compounded amount of the alkylacrylate is preferably 50% by weight or more to the total amount of the acrylic polymer, and more preferably 70 to 90% by weight. When the compounded amount of alkylacrylate is less than 50% by weight, the peeling strength becomes too large, and the pickup property may decrease.

A monomer containing a hydroxyl group that can copolymerized with the alkylacrylate is preferably used in the acrylic polymer as an essential component. Examples of the monomer containing a hydroxyl group include 2-hydroxyethyl (meth)acrylate, 2-hydroxypropyl (meth)acrylate, 4-hydroxbutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate, and (4-hydroxymethylcyclohexyl)methyl (meth)acrylate. The monomer containing a hydroxyl group can be used alone or two types or more can be used in combination.

The compounded amount of the monomer containing a hydroxyl group is preferably in a range of 1 to 30% by weight to the total amount of the monomer components, and more preferably in a range of 3 to 10% by weight. When the compounded amount of the monomer containing a hydroxyl group is less than 1% by weight, the cohesive strength of the pressure-sensitive adhesive decreases, and the pickup property may decrease. On the other hand, when the compounded amount exceeds 30% by weight, the polarity of the pressure-sensitive adhesive becomes high and the interaction with the adhesive layer becomes high. Therefore, the pickup property may decrease.

Acrylate other than alkylacrylate represented by the above-described formula may be used in the acrylic polymer as a monomer component. Examples of such acrylate include alkylacrylate other than alkylacrylate represented by the above-described formula, acrylate having an aromatic ring (arylacrylate such as phenylacrylate), and acrylate having an alicyclic hydrocarbon group (cycloalkylacrylate such as cyclopentylacrylate, cyclohexylacrylate, and isobonylacrylate). Such acrylate can be used alone or two types or more can be used in combination. Among these, other alkylacrylate and cycloalkylacrylate are suitable, and especially other alkylacrylate can be suitably used.

Examples of other alkylacrylate include alkylacrylate in which the alkyl group has 5 or fewer carbon atoms such as methylacrylate, ethylacrylate, propylacrylate, isopropylacrylate, butylacrylate, isobutylacrylate, s-butylacrylate, t-butylacrylate, pentylacrylate, and isopentylacrylate; and alkylacrylate in which the alkyl group has 11 or more (preferably 11 to 30) carbon atoms such as undecylacrylate, dodecylacrylate, tridecylacrylate, tetradecylacrylate, hexadecylacrylate, octadecylacrylate, and eicosylacrylate.

The compounded amount of the acrylate is preferably 50% by weight or more to the total amount of the monomer component, and more preferably in a range of 70 to 90% by weight. When the compounded amount of the acrylate is less than 50% by weight, the peeling power of the second pressure-sensitive adhesive layer 13 may become excessively large.

The acrylic polymer may include a unit corresponding to other monomer components that can be copolymerized with the alkylacrylate or a monomer containing a hydroxyl group as necessary for reforming cohesive strength, heat resistance, etc. Examples of other monomer components that can be copolymerized include methacrylate such as methylmethacrylate, ethylmethacrylate, propylmethacrylate, isopropylmethacrylate, butylmethacrylate, isobutylmethacrylate, s-butylmethacrylate, and t-butylmethacrylate; an acid anhydride monomer such as maleic anhydride and itaconic anhydride; a monomer containing a sulfonate group such as styrene sulfonate, allyl sulfonate, 2-(meth) acrylamide-2-methylpropane sulfonate, (meth) acrylamidepropane sulfonate, sulfopropyl(meth)acrylate, and (meth)acryloyloxynaphthalene sulfonate; a monomer containing a phosphate group such as 2-hydroxyethylacryloyl phosphate; a styrene monomer such as styrene, vinyltoluene, and alfa-methylstyrene; olefins or dienes such as ethylene, butadiene, isoprene, and isobutylene; a monomer containing a halogen atom such as vinylchloride; a monomer containing a fluorine atom such as fluorine (meth)acrylate; acrylamide, and acrylonitrile. One type or two types or more of these monomer components that can be copolymerized can be used. The used amount of these monomers that can be copolymerized is preferably 40% by weight or less to the total monomer components.

However, it is important not to use a monomer containing a carboxyl group in the present embodiment. If a monomer containing a carboxyl group is used, tackiness of the second pressure-sensitive adhesive layer 13 to the adhesive layer 14 becomes high due to a reaction between the carboxyl group and an epoxy group in the epoxy resin in the adhesive layer 14, and the peeling property of both layers decreases. Examples of such monomer containing a carboxyl group include acrylic acid, methacrylic acid, carboxyethyl (meth)acrylate, carboxypentyl (meth)acrylate, itaconic acid, maleic acid, fumaric acid, and crotonic acid.

The acrylic polymer can be obtained by polymerizing a single monomer or a mixture of two types or more of monomers. The polymerization can be performed with any method of solution polymerization (such as radical polymerization, anion polymerization, and cation polymerization), emulsion polymerization, bulk polymerization, suspension polymerization, photopolymerization (such as ultraviolet (UV) ray polymerization), etc. The content of a substance with a low molecular weight is preferably small in terms of preventing contamination to a clean adherend. In view of this, the weight average molecular weight of the acrylic polymer is preferably 350,000 to 1,000,000, and more preferably about 450,000 to 800,000.

To increase the weight-average molecular weight of the base polymer such as acrylic polymer etc., an external crosslinking agent can be suitably adopted in the second pressure-sensitive adhesive layer 13. The external crosslinking method is specifically a reaction method that involves adding and reacting a crosslinking agent such as a polyisocyanate compound, epoxy compound, aziridine compound, melamine crosslinking agent, urea resin, anhydrous compound, polyamine, carboxyl group-containing polymer. When the external crosslinking agent is used, the amount of the crosslinking agent to be used is determined suitably depending on balance with the base polymer to be crosslinked and applications thereof as the pressure-sensitive adhesive. In general, it is preferably 10 parts by weight or less, and more preferably 0.1 to 8 parts by weight to 100 parts by weight of the base polymer. The pressure-sensitive adhesive may be blended not only with the components described above but also with a wide variety of conventionally known additives such as a tackifier, and aging inhibitor, if necessary.

Examples of the ultraviolet curable monomer component to be compounded include such as an urethane oligomer, urethane(meth)acrylate, trimethylolpropane tri(meth)acrylate, tetramethylolmethane tetra(meth)acrylate, pentaerythritol tri(meth)acrylate, pentaerythritol tetra(meth)acrylate, dipentaerythritol monohydroxypenta(meth)acrylate, dipentaerythritol hexa(meth)acrylate, and 1,4-butane dioldi(meth)acrylate. Further, the ultraviolet curable oligomer component includes various types of oligomers such as an urethane based, a polyether based, a polyester based, a polycarbonate based, and a polybutadiene based oligomer, and its weight-average molecular weight is appropriately in a range of about 100 to 30,000. The compounding amount of the ultraviolet ray curable monomer component and the oligomer component can be appropriately determined to an amount in which the adhesive strength of the pressure-sensitive adhesive layer can be decreased depending on the type of the second pressure-sensitive adhesive layer 13. Generally, it is for example 5 to 500 parts by weight, and preferably about 40 to 150 parts by weight based on 100 parts by weight of the base polymer such as an acryl polymer constituting the pressure sensitive adhesive.

Further, besides the added type radiation curing-type pressure-sensitive adhesive described above, the radiation curing-type pressure-sensitive adhesive includes an internal radiation curing-type pressure-sensitive adhesive using an acryl polymer having a radical reactive carbon-carbon double bond in the polymer side chain, in the main chain, or at the end of the main chain as the base polymer. The internal radiation curing-type pressure-sensitive adhesive of an internally provided type are preferable because they do not have to contain the oligomer component, etc. that is a low molecular weight component, or most of them do not contain, they can form the second pressure-sensitive adhesive layer 13 having a stable layer structure without migrating the oligomer component, etc. in the pressure sensitive adhesive over time.

The above-mentioned base polymer, which has a carbon-carbon double bond, may be any polymer that has a carbon-carbon double bond and further has viscosity. As such a base polymer, a polymer having an acrylic polymer as a basic skeleton is preferable. Examples of the basic skeleton of the acrylic polymer include the acrylic polymers exemplified above.

The method for introducing a carbon-carbon double bond into any one of the above-mentioned acrylic polymers is not particularly limited, and may be selected from various methods. The introduction of the carbon-carbon double bond into a side chain of the polymer is easier in molecule design. The method is, for example, a method of copolymerizing a monomer having a functional group with an acrylic polymer, and then causing the resultant to condensation-react or addition-react with a compound having a functional group reactive with the above-mentioned functional group and a carbon-carbon double bond while keeping the radial ray curability of the carbon-carbon double bond.

Examples of the combination of these functional groups include a carboxylic acid group and an epoxy group; a carboxylic acid group and an aziridine group; and a hydroxyl group and an isocyanate group. Of these combinations, the combination of a hydroxyl group and an isocyanate group is preferable from the viewpoint of the easiness of reaction tracing. If the above-mentioned acrylic polymer, which has a carbon-carbon double bond, can be produced by the combination of these functional groups, each of the functional groups may be present on any one of the acrylic polymer and the above-mentioned compound. It is preferable for the above-mentioned preferable combination that the acrylic polymer has the hydroxyl group and the above-mentioned compound has the isocyanate group. Examples of the isocyanate compound in this case, which has a carbon-carbon double bond, include methacryloyl isocyanate, 2-methacryloyloxyethyl isocyanate, and m-isopropenyl-α,α-dimethylbenzyl isocyanate. The used acrylic polymer may be an acrylic polymer copolymerized with any one of the hydroxyl-containing monomers exemplified above, or an ether compound such as 2-hydroxyethyl vinyl ether, 4-hydroxybutyl vinyl ether or diethylene glycol monovinyl ether.

The intrinsic type radial ray curable adhesive may be made only of the above-mentioned base polymer (in particular, the acrylic polymer), which has a carbon-carbon double bond. However, the above-mentioned radial ray curable monomer component or oligomer component may be incorporated into the base polymer to such an extent that properties of the adhesive are not deteriorated. The amount of the radial ray curable oligomer component or the like is usually 30 parts or less by weight, preferably from 0 to 10 parts by weight for 100 parts by weight of the base polymer.

In the case that the radial ray curable adhesive is cured with ultraviolet rays or the like, a photopolymerization initiator is incorporated into the adhesive. Examples of the photopolymerization initiator include α-ketol compounds such as 4-(2-hydroxyethoxy)phenyl (2-hydroxy-2-propyl) ketone, α-hydroxy-α,α′-dimethylacetophenone, 2-methyl-2-hydroxypropiophenone, and 1-hydroxycyclohexyl phenyl ketone; acetophenone compounds such as methoxyacetophenone, 2,2-dimethoxy-2-phenylacetophenone, 2,2-diethoxyacetophenone, and 2-methyl-1-[4-(methylthio)-phenyl]-2-morpholinopropane-1; benzoin ether compounds such as benzoin ethyl ether, benzoin isopropyl ether, and anisoin methyl ether; ketal compounds such as benzyl dimethyl ketal; aromatic sulfonyl chloride compounds such as 2-naphthalenesulfonyl chloride; optically active oxime compounds such as 1-phenone-1,1-propanedione-2-(o-ethoxycarbonyl)oxime; benzophenone compounds such as benzophenone, benzoylbenzoic acid, and 3,3′-dimethyl-4-methoxybenzophenone; thioxanthone compound such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone, and 2,4-diisopropylthioxanthone; camphorquinone; halogenated ketones; acylphosphonoxides; and acylphosphonates. The amount of the photopolymerization initiator to be blended is, for example, from about 0.05 to 20 parts by weight for 100 parts by weight of the acrylic polymer or the like which constitutes the adhesive as a base polymer.

Further, examples of the ultraviolet curing type pressure-sensitive adhesive include such as an acryl pressure-sensitive adhesive which contains an addition-polymerizable compound having two or more unsaturated bonds, a photopolymerizable compound such as alkoxysilane having an epoxy group, and a photopolymerization initiator such as a carbonyl compound, an organic sulfur compound, a peroxide, an amine, and an onium salt compound, which are disclosed in JP-A No. 60-196956. Examples of the above addition-polymerizable compound having two or more unsaturated bonds include such as polyvalent alcohol ester or oligoester of acryl acid or methacrylic acid and an epoxy or a urethane compound. Moreover, when curing hinderance due to oxygen occurs during radiation irradiation, it is preferable to shield oxygen (air) from the surface of the radiation curing-type second pressure-sensitive adhesive layer 13. Examples of the method of shielding include a method of covering the surface of the second pressure-sensitive adhesive layer 13 with a separator and a method of performing irradiation with radiation such as an ultraviolet ray in a nitrogen gas atmosphere.

The thickness of the second pressure-sensitive adhesive 13 is not especially limited. However, it is preferably about 10 to 100 μm, more preferably 15 to 80 μm, and further preferably 20 to 50 μm from the viewpoints of preventing chipping of the chip cut surface, fixing and holding of the adhesive layer 14, and reducing the cutting debris. Moreover, the second pressure-sensitive adhesive layer 13 may be any of a single layer and multilayers.

The shear storage modulus of the second pressure-sensitive adhesive layer 13 at 23° C. and 150° C. is preferably 5×10⁴ to 1×10¹⁰ Pa, and more preferably 1×10⁵ to 1×10⁸ Pa. When the shear storage modulus is less than 5×10⁴ Pa, the peeling of the second pressure-sensitive adhesive layer 13 and the adhesive layer 14 may become difficult. On the other hand, when the shear storage modulus exceeds 1×10¹⁰ Pa, adhesion between the second pressure-sensitive adhesive 13 and the adhesive layer 14 may decrease. The shear storage modulus of the second pressure-sensitive adhesive layer 13 is a value that can be obtained in the following manner. First, the pressure-sensitive adhesive layer is formed into a cylinder of about 1.5 mm thickness and 7.9 mm outer diameter. Next, using an ARES viscoelasticity measurement apparatus manufactured by Rheometric Scientific, Inc. as a dynamic viscoelasticity measurement apparatus, the second pressure-sensitive adhesive layer 13 is installed into a jig of a parallel plate, and the temperature is changed from 23° C. to 150° C. at a rate of temperature rise of 5° C./min while applying shear strain of 0.1% (23° C.) and 0.3% (150° C.) and 1 Hz of frequency with a shear mode. The shear storage modulus at 23° C. and 150° C. can be obtained by measuring the modulus at this time. If the second pressure-sensitive adhesive layer 13 is a radiation curing type, the value of the shear storage modulus is a value after the radiation curing. The shear storage modulus can be appropriately adjusted by adding an external crosslinking agent, for example.

The surface free energy at the pasting surface of the second pressure-sensitive adhesive layer 13 to the adhesive layer 14 is preferably 30 mJ/m² or less, more preferably 1 to 30 mJ/m², further preferably 15 to 30 mJ/m², and especially preferably 20 to 28 mJ/m². When the surface free energy exceeds 30 mJ/m², tackiness of the second pressure-sensitive adhesive layer 13 to the adhesive layer 14 becomes too large, and the pickup property may decrease. The surface free energy at the pasting surface of the second pressure-sensitive adhesive layer precursor to the adhesive layer 14 is preferably 30 mJ/m² or less, more preferably 1 to 30 mJ/m², further preferably 15 to 30 mJ/m², and especially preferably 20 to 28 mJ/m². When the surface free energy exceeds 30 mJ/m², tackiness of the second pressure-sensitive adhesive layer 13 to the adhesive layer 14 becomes too large, and the pickup property may decrease. The surface free energy of the second pressure-sensitive adhesive layer 13 or the second pressure-sensitive adhesive layer precursor can be appropriately adjusted by adding an external crosslinking agent, for example. Moreover, the surface free energy can be calculated with the following method. First, a contact angle (θ(rad)) is measured using water and methylene iodide to the surface of the second pressure-sensitive adhesive layer 13. Next, the surface free energy (γₛ) is calculated with the following formula using this measured contact angle value and known values in documents as a value of the surface free energy of the contact angle measurement liquid.

[Formula 1]

γₛ=γₛ^{d}+γₛ^{p} (1)

γ_{L}=γ_{L}^{d}+γ_{L}^{p} (2)

(1+cos θ)γ_{L}=2(γₛ^{d}γ_{L}^{d})^{1/2}+2(γₛ^{p}γ_{L}^{p})^{1/2} (3)

Wherein, each symbol in Formulae (1) to (3) is as follows.

θ: a contact angle (rad) measured from dropping of water or methylene iodide droplets

γₛ: surface free energy (mJ/m²) of the second pressure-sensitive adhesive layer 13

γₛ^{d}: a dispersion component of the surface free energy (mJ/m²) of the second pressure-sensitive adhesive layer 13

γₛ^{p}: a polar component of the surface free energy (mJ/m²) of the second pressure-sensitive adhesive layer 13

γ_{L}: surface free energy (mJ/m²) of water or methylene iodide

γ_{L}^{d}: a dispersion component of the surface free energy (mJ/m²) of water or methylene iodide

γ_{L}^{p}: a polar component of the surface free energy (mJ/m²) of water or methylene iodide

The known values of the surface free energy in documents are as follows.

Water: dispersion component (γ_{L}^{d}) 21.8 mJ/m², polar component (γ_{L}^{p}) 51.0 mJ/m²

Methylene iodide: dispersion component (γ_{L}^{d}) 49.5 mJ/m², polar component (γ_{L}^{p}) 1.3 mJ/m²

The contact angles of water and methylene iodide at the pasting surface of the second pressure-sensitive adhesive layer 13 to the adhesive layer 14 are values that are obtained in the following manner. According to JIS Z8703, about 1 μL droplets of water (distilled water) or methylene iodide are dropped onto the surface of the second pressure-sensitive adhesive layer 13 under an environment of temperature 23±2° C. and relative humidity 50±5% Rh. Next, after 30 seconds of dropping, the contact angle is measured with a three-point method (an average value is used) using a surface contact angle meter “CA-X” manufactured by FACE Co.

Moreover, the second pressure-sensitive adhesive layer 13 may contain various additives (such as a coloring agent, a thickener, an extender, a filler, a tackifier, a plasticizer, an antiaging agent, an antioxidant, a surfactant, and a crosslinking agent) in the scope not impairing the effects of the present invention.

The bending stiffness S calculated with E×I of a structure in which the base layer 11, the first pressure-sensitive adhesive layer 12, and the second pressure-sensitive adhesive layer 13 are laminated is preferably in a range of 5.0×10⁴ to 7.0×10⁵, (wherein, I is the second moment of area represented with b×T³/12, b is 10 (mm) that is the width of a test piece of the structure, T is the thickness (mm) of the structure, and E is the tensile storage modulus (Pa) at 25° C. of the structure). The bending stiffness S is more preferably in a range of 6.0×10⁴ to 6.0×10⁵, and further preferably in a range of 7.0×10⁴ to 5.0×10⁵. By making the bending stiffness S be 5.0×10⁴ or more, the stiffness of the structure can be maintained, and pasting of a wafer without any wrinkles becomes possible. On the other hand, by making the bending stiffness S be 7.0×10⁵ or less, the structure bends properly during pickup, and a stable pickup can be performed. The tensile modulus (Pa) at 25° C. of the structure is a value measured at a rate of temperature rise of 5° C./min using a dynamic viscoelasticity measurement apparatus (RSA-III manufactured by Rheometric Scientific Inc).

### [Adhesive Layer]

The adhesive layer 14 is provided on the second pressure-sensitive adhesive layer 13, and has an adhesive function to a semiconductor wafer, etc. As shown in FIG. 2, when the circular second pressure-sensitive adhesive layer 13 is provided inside of the dicing ring pasting portion 18 on the first pressure-sensitive adhesive layer 12, the plane shape of the adhesive layer 14 is made to be circular, and it is preferably arranged approximately concentrically with the center of the second pressure-sensitive adhesive layer 13. The plane shape of the adhesive layer 14 is larger than the second pressure-sensitive adhesive layer 13, and preferably provided so as to cover the entire surface of the second pressure-sensitive adhesive layer 13. With this, the peripheral edge part 14a (diagonally shaded areas in FIG. 2) of the adhesive layer 14 can be laminated on the first pressure-sensitive adhesive layer 12. When the adhesive layer 14 has such laminated structure, the peripheral edge part of the adhesive layer 14 has a configuration in which it is firmly adhered on the first pressure-sensitive adhesive layer 12 and not on the second pressure-sensitive adhesive layer 13 which has a light peeling property. As a result, the adhesive layer 14 can be prevented from peeling and coming off from the second pressure-sensitive adhesive layer 13 during dicing.

An example of constituent materials of the adhesive layer 14 is a material in which a thermoplastic resin and a thermosetting resin are used together. Further, a thermoplastic resin or a thermosetting resin can be used alone. The adhesive layer 14 made only of a single adhesive layer, and a multi-layered adhesive sheet wherein an adhesive layer or adhesive layers is/are formed on a single face or both faces of a core member. Examples of the core member include films (such as polyimide film, polyester film, polyethylene terephthalate film, polyethylene naphthalate film, and polycarbonate film); resin substrates which are reinforced with glass fiber or plastic nonwoven finer; silicon substrates; and glass substrates.

Examples of the thermoplastic resin include natural rubber, butyl rubber, isoprene rubber, chloroprene rubber, ethylene/vinyl acetate copolymer, ethylene/acrylic acid copolymer, ethylene/acrylic ester copolymer, polybutadiene resin, polycarbonate resin, thermoplastic polyimide resin, polyamide resins such as 6-nylon and 6,6-nylon, phenoxy resin, acrylic resin, saturated polyester resins such as PET and PBT, polyamideimide resin, and fluorine-contained resin. These thermoplastic resins may be used alone or in combination of two or more thereof. Of these thermoplastic resins, acrylic resin is particularly preferable since the resin contains ionic impurities in only a small amount and has a high heat resistance so as to make it possible to ensure the reliability of the semiconductor element.

The acrylic resin is not limited to any especial kind, and may be, for example, a polymer comprising, as a component or components, one or more esters of acrylic acid or methacrylic acid having a linear or branched alkyl group having 30 or less carbon atoms, in particular, 4 to 18 carbon atoms. Examples of the alkyl group include methyl, ethyl, propyl, isopropyl, n-butyl, t-butyl, isobutyl, amyl, isoamyl, hexyl, heptyl, cyclohexyl, 2-ethylhexyl, octyl, isooctyl, nonyl, isononyl, decyl, isodecyl, undecyl, lauryl, tridecyl, tetradecyl, stearyl, octadecyl, and dodecyl groups.

A different monomer which constitutes the above-mentioned polymer is not limited to any especial kind, and examples thereof include carboxyl-containing monomers such as acrylic acid, methacrylic acid, carboxyethyl acrylate, carboxypentyl acrylate, itaconic acid, maleic acid, fumaric acid, and crotonic acid; acid anhydride monomers such as maleic anhydride and itaconic anhydride; hydroxyl-containing monomers such as 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth) acrylate, 10-hydroxydecyl (meth) acrylate, 12-hydroxylauryl (meth)acrylate, and (4-hydroxymethylcyclohexyl)methylacrylate; monomers which contain a sulfonic acid group, such as styrenesulfonic acid, allylsulfonic acid, 2-(meth) acrylamide-2-methylpropanesulfonic acid, (meth)acrylamidepropane sulfonic acid, sulfopropyl (meth)acrylate, and (meth) acryloyloxynaphthalenesulfonic acid; and monomers which contain a phosphoric acid group, such as 2-hydroxyethylacryloyl phosphate.

An acrylic copolymer is preferable as the acrylic resin. The monomer component that is used in the acrylic copolymer is not especially limited, and examples thereof include butylacrylate and ethylacrylate. In the present invention, a copolymer is preferable that is configured by including 10 to 60% by weight of butylacrylate and 40 to 90% by weight of ethylacrylate to the entire monomer component.

Further, other monomer components that can be copolymerized with the above-described monomer component are not especially limited, and examples thereof include acrylonitrile. The used amount of these monomer components that can be copolymerized is preferably 1 to 20% by weight to the total monomer components. Reformation of the cohesive strength, tackiness, etc. can be attempted by including other monomer components in the above-described range.

The polymerization method of the acrylic copolymer is not especially limited and can adopt a conventionally known method such as a solution polymerization method, a bulk polymerization method, a suspension polymerization method, and an emulsion polymerization method.

The glass transition temperature (Tg) of the acrylic copolymer is preferably −30 to 10° C., and more preferably −25 to 8° C. By making the glass transition temperature be −30° C. or more, the storage modulus of the adhesive layer 14 at a high temperature (for example, 100 to 200° C.) can be secured. On the other hand, by making the glass transition temperature be 10° C. or less, good adhesion and stickiness to a semiconductor wafer can be exhibited.

The weight average molecular weight of the acrylic copolymer is preferably 100,000 or more, more preferably 600,000 to 1,200,000, and especially preferably 700,000 to 1,000,000. By making the weight average molecular weight be 100,000 or more, excellent tackiness to an adherend such as a wiring board, a semiconductor element, and the surface of a semiconductor wafer at a high temperature can be achieved, and heat resistance can be improved. By making the weight average molecular weight be 1,200,000 or less, the acrylic copolymer can be dissolved into an organic solvent easily. The weight average molecular weight is a polystyrene converted value obtained by using a calibration curve of standard polystyrene with gel permeation chromatography (GPC).

Examples of the above-mentioned thermosetting resin include phenol resin, amino resin, unsaturated polyester resin, epoxy resin, polyurethane resin, silicone resin, and thermosetting polyimide resin. These resins may be used alone or in combination of two or more thereof. Particularly preferable is epoxy resin, which contains ionic impurities which corrode semiconductor elements in only a small amount. As the curing agent of the epoxy resin, phenol resin is preferable.

The epoxy resin may be any epoxy resin that is ordinarily used as an adhesive composition. Examples thereof include bifunctional or polyfunctional epoxy resins such as bisphenol A type, bisphenol F type, bisphenol S type, brominated bisphenol A type, hydrogenated bisphenol A type, bisphenol AF type, biphenyl type, naphthalene type, fluorene type, phenol Novolak type, orthocresol Novolak type, tris-hydroxyphenylmethane type, and tetraphenylolethane type epoxy resins; hydantoin type epoxy resins; tris-glycicylisocyanurate type epoxy resins; and glycidylamine type epoxy resins. These may be used alone or in combination of two or more thereof. Among these epoxy resins, particularly preferable are Novolak type epoxy resin, biphenyl type epoxy resin, tris-hydroxyphenylmethane type epoxy resin, and tetraphenylolethane type epoxy resin, since these epoxy resins are rich in reactivity with phenol resin as an agent for curing the epoxy resin and are superior in heat resistance and so on. The content of ionic impurities, etc. that corrodes a semiconductor element in the epoxy resin are low.

The phenol resin is a resin acting as a curing agent for the epoxy resin. Examples thereof include Novolak type phenol resins such as phenol Novolak resin, phenol aralkyl resin, cresol Novolak resin, tert-butylphenol Novolak resin and nonylphenol Novolak resin; resol type phenol resins; and polyoxystyrenes such as poly(p-oxystyrene). These may be used alone or in combination of two or more thereof. Among these phenol resins, a biphenyl type phenol novolac resin shown by the following formula and a phenol aralkyl resin are preferable.

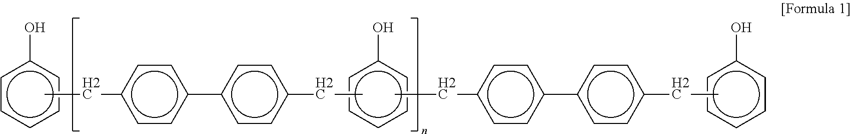

n is a natural number of 0 to 10.

n is preferably a natural number of 0 to 10, and more preferably a natural number of 0 to 5. By making n in this range, fluidity of the adhesive layer 14 can be secured.

About the blend ratio between the epoxy resin and the phenol resin, for example, the phenol resin is blended with the epoxy resin in such a manner that the hydroxyl groups in the phenol resin is preferably from 0.5 to 2.0 equivalents, more preferably from 0.8 to 1.2 equivalents per equivalent of the epoxy groups in the epoxy resin component. If the blend ratio between the two is out of the range, curing reaction therebetween does not advance sufficiently so that properties of the cured epoxy resin easily deteriorate.

In the present invention, adhesive layer comprising the epoxy resin, the phenol resin, and an acrylic resin is particularly preferable. Since these resins contain ionic impurities in only a small amount and have high heat resistance, the reliability of the semiconductor element can be ensured. About the blend ratio in this case, the amount of the mixture of the epoxy resin and the phenol resin is from 10 to 200 parts by weight for 100 parts by weight of the acrylic resin component.

In order to crosslink the adhesive layer 14 of the present invention to some extent in advance, it is preferable to add, as a crosslinking agent, a polyfunctional compound which reacts with functional groups of molecular chain terminals of the above-mentioned polymer to the materials used when the sheet 12 is produced. In this way, the adhesive property of the sheet at high temperatures is improved so as to improve the heat resistance.

The crosslinking agent may be polyisocyanate compounds, such as tolylene diisocyanate, diphenylmethane diisocyanate, p-phenylene diisocyanate, 1,5-naphthalene diisocyanate, and adducts of polyhydric alcohol and diisocyanate. The amount of the crosslinking agent to be added is preferably set to 0.05 to 7 parts by weight for 100 parts by weight of the above-mentioned polymer. If the amount of the crosslinking agent to be added is more than 7 parts by weight, the adhesive force is unfavorably lowered. On the other hand, if the adding amount is less than 0.05 part by weight, the cohesive force is unfavorably insufficient. A different polyfunctional compound, such as an epoxy resin, together with the polyisocyanate compound may be incorporated if necessary.

An inorganic filler can be appropriately compounded in the adhesive layer 14. The compounding of the inorganic filler gives the surface of the adhesive layer 14 unevenness. Further, the compounding of the inorganic filler imparts conductivity and enables improvement of thermal conductivity, adjustment of the storage modulus, and the like.

Examples of the inorganic fillers include various inorganic powders made of the following: a ceramic such as silica, clay, plaster, calcium carbonate, barium sulfate, aluminum oxide, beryllium oxide, silicon carbide or silicon nitride; a metal such as aluminum, copper, silver, gold, nickel, chromium, lead, tin, zinc, palladium or solder, or an alloy thereof; and carbon. These may be used alone or in combination of two or more thereof. Among these, silica, in particular fused silica is preferably used.

The average particle size of the inorganic filler is preferably in a range of 0.1 to 5 μm, and more preferably in a range of 0.2 to 3 μm. When the average particle size of the inorganic filler is less than 0.1 μm, it becomes difficult to make Ra of the adhesive layer be 0.15 μm or more. On the other hand, when the average particle size exceeds 5 μm, it becomes difficult to make Ra be less than 1 μm. In the present invention, inorganic fillers having a different average particle size can be used in combination. The average particle size is a value obtained by a light intensity type particle size distribution meter (LA-910 manufactured by HORIBA, Ltd.), for example.

The compounding amount of the inorganic filler is preferably set to 20 to 80 parts by weight to 100 parts by weight of the organic resin component. It is especially preferably 20 to 70 parts by weight. When the compounding amount of the inorganic filler is less than 20 parts by weight, the adhesive layer 14 hardens when it is exposed to a thermal history of high temperature for a long time due to a decrease of the heat resistance, and the fluidity and embedding property may decrease. When the compounding amount of the inorganic filler exceeds 80 parts by weight, the storage modulus of the adhesive layer 14 becomes large. Therefore, stress relaxation of the hardened adhesive becomes difficult, and the embedding property to the unevenness may decrease in a sealing step.

If necessary, other additives besides the inorganic filler may be incorporated into the adhesive layer 14. Examples thereof include a flame retardant, a silane coupling agent, and an ion trapping agent. Examples of the flame retardant include antimony trioxide, antimony pentaoxide, and brominated epoxy resin. These may be used alone or in combination of two or more thereof. Examples of the silane coupling agent include β-(3,4-epoxycyclohexyl)ethyltrimethoxysilane, γ-glycidoxypropyltrimethoxysilane, and γ-glycidoxypropylmethyldiethoxysilane. These may be used alone or in combination of two or more thereof. Examples of the ion trapping agent include hydrotalcite and bismuth hydroxide. These may be used alone or in combination of two or more thereof.

The adhesive layer 14 may be colored as necessary. The color of the adhesive layer 14 that is exhibited by coloring is not especially limited. However, preferable examples of the color include black, blue, red, and green. When the adhesive layer 14 is used as a die-bonding film, it is not normally colored (it may be colored). However, the adhesive layer 14 is normally colored when it is used as a film for the backside of a flip-chip semiconductor. Known coloring agents such as pigments and dyes can be appropriately selected and used in the coloring.

The thickness of the adhesive layer 14 (in the case that the film is a laminate, the total thickness thereof) is not particularly limited, and is, for example, from about 5 to 100 μm, preferably from about 5 to 50 μm.

The adhesive layer of the present invention can be used as a die-bonding film and a film for the backside of a flip-chip semiconductor. The film for the backside of a flip-chip semiconductor is used to protect the backside of a semiconductor chip (the backside that is exposed) when mounting the semiconductor chip on a substrate by flip-chip bonding.

### [Peeling Power Between Each Layer]

The peeling strength X between the second pressure-sensitive adhesive layer 13 and the adhesive layer 14 is preferably in a range of 0.01 to 0.2 N/20 mm, and more preferably in a range of 0.015 to 0.18 N/20 mm. By making the peeling strength X be 0.01 N/20 mm or more, the generation of chip fly of the semiconductor chip that is caused by the peeling between these two layers can be prevented when dicing the semiconductor wafer, for example. On the other hand, by making the peeling strength X be 0.2 N/20 mm or less, the semiconductor chip can be picked up satisfactorily even when the step of irradiating with radiation is omitted.

The peeling strength Y between the first pressure-sensitive adhesive layer 12 and the second pressure-sensitive adhesive layer 13 is preferably in a range of 0.2 to 10 N/20 mm, and more preferably in a range of 0.3 to 9.5 N/20 mm. By making the peeling strength Y be 0.2 N/20 mm or more, the semiconductor wafer and the semiconductor chip can be securely fixed during dicing, for example. By making the peeling strength Y be 10 N/20 mm or less, the second pressure-sensitive adhesive layer 13 can be peeled from the first pressure-sensitive adhesive layer 12, and the laminated film can be reused as a carrier tape that is configured with the base layer 11 and the first pressure-sensitive adhesive layer 12.

The ratio (Y/X) of the peeling strength Y between the first pressure-sensitive adhesive layer 12 and the second pressure-sensitive adhesive layer 13 to the peeling strength X between the second pressure-sensitive adhesive layer 13 and the adhesive layer 14 is preferably in a range of 3 to 500, and more preferably in a range of 4 to 400. By making the ratio (Y/X) of the peeling strength Y to the peeling strength X be 3 or more, the peeling interface during pickup of the semiconductor chip can be made to be the boundary of the second pressure-sensitive adhesive layer 13 and the adhesive layer 14. On the other hand, by making the ratio (Y/X) be 500 or less, chip fly and releasing of the adhesive layer during dicing are suppressed, and a stable dicing can be performed.

The peeling strength between the first pressure-sensitive adhesive layer 12 and a SUS304-BA plate is preferably in a range of 0.2 to 11 N/20 mm, and more preferably in a range of 0.3 to 9.5 N/20 mm. By making the peeling strength be 0.2 N/20 mm or more, the dicing ring can be securely adhered and fixed, and the dicing can be performed well. On the other hand, by making the peeling strength be 11 N/20 mm or less, generation of adhesive residue on the dicing ring can be reduced when peeling the dicing ring after use from the first pressure-sensitive adhesive layer 12.

### [Separator]

The separator 15 has a function as a protective material to protect the adhesive layer 14 until it is used. As shown in FIG. 2, the separator 15 also protects the first pressure-sensitive adhesive layer 12 when the second pressure-sensitive adhesive layer 13 and the adhesive layer 14 are provided inside of the dicing ring pasting portion 18. The separator 15 can be also used as a base when transferring the adhesive layer 14 to the second pressure-sensitive adhesive layer 13. The separator 15 is peeled when pasting the semiconductor wafer onto the adhesive layer 14. Polyethylenetelephthalate (PET), polyethylene, polypropylene, a plastic film, a paper, etc. whose surface is coated with a peeling agent such as a fluorine based peeling agent and a long chain alkylacrylate based peeling agent can be also used as the separator 15.

### (Method of Manufacturing a Film for Manufacturing a Semiconductor Device)

Next, a method of manufacturing a film for manufacturing a semiconductor device of the present invention is described with reference to a film 1 for manufacturing a semiconductor device as an example. First, the base layer 11 can be formed by a conventionally known film-forming method. The film-forming method includes, for example, a calendar film-forming method, a casting method in an organic solvent, an inflation extrusion method in a closed system, a T-die extrusion method, a co-extrusion method, and a dry lamination method.

Next, the pressure-sensitive adhesive layer 12 is formed on the base layer 11. That is, the first pressure-sensitive adhesive layer 12 is formed by forming a coating film by applying a pressure-sensitive adhesive composition onto the base layer 11 and then by drying the coating film under a prescribed condition (by heat-crosslinking as necessary). The application method is not especially limited, and examples thereof include roll coating, screen coating, and gravure coating. The drying condition is variously set depending on the thickness and materials of the coating film. Specifically, the drying is performed at a drying temperature of 80 to 150° C. and a drying time of 0.5 to 5 minutes, for example. The first pressure-sensitive adhesive layer 12 may also be formed by forming a coating film by applying a pressure-sensitive adhesive composition onto a separator and then drying the coating film under the above-described drying condition. After that, the first pressure-sensitive adhesive layer 12 is transferred onto the base layer 11.

Next, the second pressure-sensitive adhesive layer 13 is formed on the first pressure-sensitive adhesive layer 12. That is, the second pressure-sensitive adhesive layer precursor is formed by forming a coating film by applying a radiation curing-type pressure-sensitive adhesive composition onto the separator and then by drying the coating film under a prescribed condition (by heat-crosslinking as necessary). The application method is not especially limited, and examples thereof include roll coating, screen coating, and gravure coating. The drying condition is variously set depending on the thickness and materials of the coating film. Specifically, the drying is performed at a drying temperature of 80 to 150° C. and a drying time of 0.5 to 5 minutes, for example. The second pressure-sensitive adhesive layer precursor may also be formed by forming a coating film by applying a pressure-sensitive adhesive composition onto the separator and then drying the coating film under the above-described drying condition.

The second pressure-sensitive adhesive layer precursor formed in such a manner is irradiated with radiation, thereby forming the second pressure-sensitive adhesive layer 13. When an ultraviolet ray is used as radiation, the irradiation intensity as the irradiation condition is preferably in a range of 50 to 1000 mJ/cm², and more preferably in a range of 100 to 800 mJ/cm². When the irradiation with ultraviolet rays is less than 50 mJ/cm², the curing of the second pressure-sensitive adhesive layer 13 may become insufficient. As a result, adhesion with the adhesive layer 14 increases, and this causes a decrease of the pickup property. Further, adhesive residue is generated on the adhesive layer 14 after pickup. On the other hand, when the irradiation with ultraviolet rays exceeds 1000 mJ/cm², the curing of the second pressure-sensitive adhesive layer 13 proceeds excessively, the tensile modulus becomes too large, and expandability decreases. Further, the adhesive power decreases excessively, and consequently chip fly may generate when dicing the semiconductor wafer.

After that, the second pressure-sensitive adhesive layer 13 that is cured by radiation irradiation is transferred onto the first pressure-sensitive adhesive layer 12. In the present embodiment, the second pressure-sensitive adhesive layer 13 may be also formed by transferring the second pressure-sensitive adhesive layer precursor onto the first pressure-sensitive adhesive layer 12 and then performing radiation irradiation to the first pressure-sensitive adhesive layer precursor. When an ultraviolet ray is used as radiation, the irradiation intensity as the irradiation condition in this case is preferably in a range of 50 to 1000 mJ/cm², and more preferably in a range of 100 to 800 mJ/cm². When the irradiation with ultraviolet rays is less than 50 mJ/cm², the curing of the second pressure-sensitive adhesive layer 13 may become insufficient. As a result, adhesion with the adhesive layer 14 increases, and this causes a decrease of the pickup property. Further, adhesive residue is generated on the adhesive layer 14 after pickup. On the other hand, when the irradiation with ultraviolet rays exceeds 1000 mJ/cm², the curing of the second pressure-sensitive adhesive layer 13 proceeds excessively, the tensile modulus becomes too large, and expandability decreases. Further, the adhesive power decreases excessively, and consequently chip fly may generate when dicing the semiconductor wafer.

Next, the adhesive layer 14 is formed on the second pressure-sensitive adhesive layer 13. That is, the adhesive layer 14 is formed by applying an adhesive composition for forming the adhesive layer 14 onto a peeling paper so as to have a prescribed thickness and by drying at a prescribed condition. The film 1 for manufacturing a semiconductor device according to the present embodiment can be formed by transferring the adhesive layer 14 onto the second pressure-sensitive adhesive layer 13. The transferring of the adhesive layer 14 may also be preformed onto the second pressure-sensitive adhesive layer precursor. In this case, the second pressure-sensitive adhesive layer 13 is formed by transferring the adhesive layer 14 onto the second pressure-sensitive adhesive layer precursor and then by irradiating the second pressure-sensitive adhesive layer precursor with radiation. The irradiation condition of radiation in this case is according to the case that the second pressure-sensitive adhesive layer precursor is transferred onto the first pressure-sensitive adhesive layer 12.

### (Method of Manufacturing a Semiconductor Device)

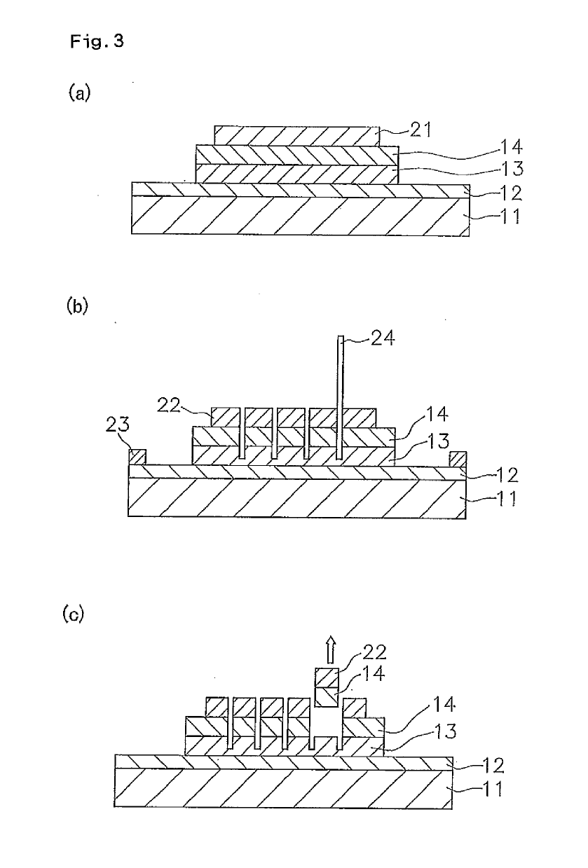

A method of manufacturing a semiconductor device using the film 1 for manufacturing a semiconductor device is described below with reference to FIGS. 3A to 3C. FIGS. 3A to 3C are schematic sectional views each showing dicing of a semiconductor wafer that is pasted on the adhesive layer of the film for manufacturing a semiconductor device.

First, as shown in FIG. 3A, a semiconductor wafer 21 is adhered on the adhesive layer 14 in the film 1 for manufacturing a semiconductor device by pressing, and fixing this by adhering and holding (a mounting step). This step is performed while pressing with pressing means such as a pressing roll. The pasting condition is not especially limited. However, the pasting can be normally performed at a pasting temperature of 25 to 80° C., a pasting speed of 1 to 100 mm/sec, and a pasting pressure of 0.05 to 1 MPa.

Next, dicing of the semiconductor wafer 21 is performed as shown in FIG. 3B. With this, a semiconductor chip 22 is formed by cutting the semiconductor wafer 21 and individualizing into pieces having a prescribed size. The dicing is performed from the circuit surface side of the semiconductor wafer 21 with a normal method, for example. A dicing ring 23 is provided on the dicing ring pasting portion 18 on the first pressure-sensitive adhesive layer 12. In this step, the cutting with a dicing blade 24 is performed to a portion of the second pressure-sensitive adhesive layer 13 and does not reach to the first pressure-sensitive adhesive layer 12. Because the second pressure-sensitive adhesive layer 13 is cured with radiation in advance, the generation of adhesive protruding (burrs) at the cut surface can be reduced even when it is cut by dicing. a result, two cut surfaces are prevented from re-attaching (blocking) to each other, and the pickup described later can be performed better. Because the base layer 11 and the first pressure-sensitive adhesive layer 12 cannot be cut, the string-like cutting debris that are generated due to the cutting of the base layer 11 are prevented from attaching to the side surface of the semiconductor chip 21, etc. as burrs or whiskers, and a low contamination property can be attempted. Burrs, etc. that are generated due to the cutting of the first pressure-sensitive adhesive layer 12 can be also prevented. The dicing apparatus that is used in this step is not especially limited, and a conventionally known apparatus can be used. Further, because the semiconductor wafer 21 is adhered and fixed by the adhesive layer 14, chip crack and chip fly can be suppressed, and damage of the semiconductor wafer 21 can be suppressed.

Next, expanding of the film 1 for manufacturing a semiconductor device is performed. The expanding is performed using a conventionally known expanding apparatus. The expanding apparatus has a doughnut-shaped outer ring that can push the film 1 for manufacturing a semiconductor device downward and an inner ring having a smaller diameter than that of the outer ring to support the film 1 for manufacturing a semiconductor device through a dicing ring.

Subsequently, as shown in FIG. 3C, pickup of the semiconductor chip 22 is performed to peel the semiconductor chip 22 that is adhered and fixed to the film for manufacturing a semiconductor device 1. Because the second pressure-sensitive adhesive layer 13 is cured by radiation irradiation in advance, the pickup can be performed without irradiating with radiation. The method of pickup is not especially limited, and various conventionally known methods can be adopted. An example thereof includes a method of pushing up an individual semiconductor chip 22 from the side of the film 1 for manufacturing a semiconductor device with a needle and picking up the pushed semiconductor chip 22 with a pickup apparatus. Because the peeling property of the second pressure-sensitive adhesive layer 13 and the adhesive layer 14 is good in the film 1 for manufacturing a semiconductor device of the present invention, the pickup can be performed with an improved yield even when the number of needles is decreased or when the amount of pushing up is made to be small, for example.

The semiconductor chip 22 that is picked up is adhered and fixed to an adherend through the adhesive layer 14 (die bonding). The adherend is placed on a heat block 9. Examples of the adherend include such as a lead frame, a TAB film, a substrate, and a semiconductor chip separately produced. The adherend may be a deformable adherend that are easily deformed, or may be a non-deformable adherend (a semiconductor wafer, etc.) that is difficult to deform, for example.

A conventionally known substrate can be used as the substrate. Further, a metal lead frame such as a Cu lead frame and a 42 Alloy lead frame and an organic substrate composed of glass epoxy, BT (bismaleimide-triazine), and polyimide can be used as the lead frame. However, the present invention is not limited to this, and includes a circuit substrate that can be used by mounting a semiconductor element and electrically connecting with the semiconductor element.

When the adhesive layer 14 is a heat curing type, the semiconductor chip 22 is adhered and fixed to the adherend by heat curing, and the heat resistant strength is improved. A product obtained by adhering and fixing the semiconductor chip 22 to a substrate through the adhesive layer 14 or the like can be subjected to a reflow step. After that, wire bonding is performed to electrically connect the tip of the terminal (inner lead) of a substrate and an electrode pad on the semiconductor chip 22 with a bonding wire, the semiconductor chip is sealed with a sealing resin, and the sealing resin is postcured. With this, the semiconductor device according to the present embodiment is produced.

Below, preferred examples of the present invention are explained in detail. However, materials, addition amounts, and the like described in these examples are not intended to limit the scope of the present invention, and are only examples for explanation as long as there is no description of limitation in particular.

### Example 1

### <Production of the Second Pressure-Sensitive Adhesive Layer>

An acrylic polymer X was obtained by placing 80 parts by weight of 2-ethylhexyl acrylate (2EHA), 20 parts by weight of 2-hydroxyethyl acrylate (HEA), and 65 parts by weight of toluene in a reactor equipped with a cooling tube, a nitrogen introducing tube, a thermometer, and a stirring apparatus and polymerizing the mixture at 61° C. in a nitrogen stream for 6 hours.

An acrylic polymer Y was obtained by adding 24.1 parts by weight of 2-methacryloyloxyethyl isocyanate (MOI) (90 mol % to HEA) into 100 parts by weight the acrylic polymer X and performing an addition reaction at 50 C in an air stream for 48 hours.

Next, a pressure-sensitive adhesive solution was prepared by adding 3 parts by weight of a polyisocyanate compound (Coronate L manufactured by Nippon Polyurethane Industry Co., Ltd.) and 5 parts by weight of a photopolymerization initiator (Irgacure 651 manufactured by Ciba Specialty Chemicals Inc.) into 100 parts by weight of the acrylic polymer Y.

A radiation curing-type second pressure-sensitive adhesive layer precursor having a thickness of 30 μm was formed by applying the prepared pressure-sensitive adhesive solution onto the surface of a PET film having a thickness of 50 μm on which a silicone treatment was performed, and heat-crosslinking at 80° C. for 3 minutes. After that, a second pressure-sensitive adhesive layer was produced by irradiating with ultraviolet rays at a cumulative radiation of ultraviolet rays of 300 mJ/cm² using an ultraviolet (UV) irradiation apparatus (UM-810 manufactured by Nitto Seki Co., Ltd).

### <Production of the Adhesive Layer>

An adhesive composition solution having a concentration of 23.6% by weight was obtained by dissolving 50 parts by weight of an epoxy resin (EPPN501HY manufactured by Nippon Kayaku Co., Ltd.), 50 parts by weight of a phenol resin (MEH7800 manufactured by Meiwa Plastic Industries, Ltd.), 100 parts by weight of an acrylic copolymer (REBITAL AR31 manufactured by Nogawa Chemical Co., Ltd., weight average molecular weight 700,000, glass transition point −15° C.), and 70 parts by weight of spherical silica (SO-25R manufactured by Admatechs Co., Ltd., average particle size 0.5 μm) as a filler into methylethylketone.

This adhesive composition solution was applied on a release-treated film (peel liner) composed of a 50 μm thick polyethylene terephthalate film subjected to a silicone release treatment and then dried at 130° C. for 2 minutes to produce a 25 μm thick adhesive layer.

<Production of the Film for Manufacturing a Semiconductor Device>

S-400X manufactured by Nitto Denko Co., Ltd. was used as a carrier tape in which a first pressure-sensitive adhesive layer was laminated on a base layer. The second pressure-sensitive adhesive layer that was cut out at 315 mmφ was pasted onto the first pressure-sensitive adhesive layer of this carrier tape at room temperature. After that, a film for manufacturing a semiconductor device according to the present example was produced by pasting an adhesive layer that was cut out at 330 mmφ at 40° C. so as to entirely cover the second pressure-sensitive adhesive layer.

### Example 2

In the present example, a film for manufacturing a semiconductor device according to the present example was produced in the same manner as Example 1 except that CB-700 manufactured by Nitto Denko Co., Ltd. was used as a carrier tape in which the first pressure-sensitive adhesive layer was laminated on the base layer.

### Example 3

In the present example, a film for manufacturing a semiconductor device according to the present example was produced in the same manner as Example 1 except that M-4001 manufactured by Nitto Denko Co., Ltd. was used as a carrier tape in which the first pressure-sensitive adhesive layer was laminated on the base layer.

### Example 4

In the present example, a film for manufacturing a semiconductor device according to the present example was produced in the same manner as Example 1 except that HR-4011 manufactured by Nitto Denko Co., Ltd. was used as a carrier tape in which the first pressure-sensitive adhesive layer was laminated on the base layer.

### Example 5

In the present example, a film for manufacturing a semiconductor device according to the present example was produced in the same manner as Example 1 except that V8-S manufactured by Nitto Denko Co., Ltd. was used as a carrier tape in which the first pressure-sensitive adhesive layer was laminated on the base layer.

### Example 6

In the present example, a film for manufacturing a semiconductor device according to the present example was produced in the same manner as Example 1 except that UE-1088J manufactured by Nitto Denko Co., Ltd. was used as a carrier tape in which the first pressure-sensitive adhesive layer was laminated on the base layer.

### Example 7

In the present example, a film for manufacturing a semiconductor device according to the present example was produced in the same manner as Example 1 except that UB-2130E manufactured by Nitto Denko Co., Ltd. was used as a carrier tape in which the first pressure-sensitive adhesive layer was laminated on the base layer.

### Example 8

### <Production of the Second Pressure-Sensitive Adhesive Layer>

An acrylic polymer X was obtained by placing 80 parts by weight of 2-ethylhexyl acrylate (2EHA), 20 parts by weight of 2-hydroxyethyl acrylate (HEA), and 65 parts by weight of toluene in a reactor equipped with a cooling tube, a nitrogen introducing tube, a thermometer, and a stirring apparatus and polymerizing the mixture at 61° C. in a nitrogen stream for 6 hours.

An acrylic polymer Y was obtained by adding 24.1 parts by weight of 2-methacryloyloxyethyl isocyanate (MOI) (90 mol % to HEA) into 100 parts by weight the acrylic polymer X and performing an addition reaction at 50 C in an air stream for 48 hours.

Next, a pressure-sensitive adhesive solution was prepared by adding 8 parts by weight of a polyisocyanate compound (Coronate L manufactured by Nippon Polyurethane Industry Co., Ltd.) and 5 parts by weight of a photopolymerization initiator (Irgacure 651 manufactured by Ciba Specialty Chemicals Inc.) into 100 parts by weight of the acrylic polymer Y.

A radiation curing-type second pressure-sensitive adhesive layer precursor having a thickness of 30 μm was formed by applying the prepared pressure-sensitive adhesive solution onto the surface of a PET film having a thickness of 50 μm on which a silicone treatment was performed, and heat-crosslinking at 80° C. for 3 minutes. After that, a second pressure-sensitive adhesive layer was produced by irradiating with ultraviolet rays at a cumulative radiation of ultraviolet rays of 300 mJ/cm² using an ultraviolet (UV) irradiation apparatus (UM-810 manufactured by Nitto Seki Co., Ltd).

<Production of the Adhesive Layer>

The same adhesive layer as Example 1 was used as the adhesive layer according to the present example.

<Production of the Film for Manufacturing a Semiconductor Device>

The same product as Example 1 was used as a carrier tape in which the first pressure-sensitive adhesive layer was laminated on the base layer. The second pressure-sensitive adhesive layer that was cut out at 315 mmφ was pasted onto the first pressure-sensitive adhesive layer of this carrier tape at room temperature. After that, a film for manufacturing a semiconductor device according to the present example was produced by pasting an adhesive layer that was cut out in 330 mmφ at 40° C. so as to entirely cover the second pressure-sensitive adhesive layer.

### Example 9

### <Production of a Precursor of the Second Pressure-Sensitive Adhesive Layer>

An acrylic polymer X was obtained by placing 80 parts by weight of 2-ethylhexyl acrylate (2EHA), 20 parts by weight of 2-hydroxyethyl acrylate (HEA), and 65 parts by weight of toluene in a reactor equipped with a cooling tube, a nitrogen introducing tube, a thermometer, and a stirring apparatus and polymerizing the mixture at 61° C. in a nitrogen stream for 6 hours.

An acrylic polymer Y was obtained by adding 24.1 parts by weight of 2-methacryloyloxyethyl isocyanate (MOI) (90 mol % to HEA) into 100 parts by weight the acrylic polymer X and performing an addition reaction at 50 C in an air stream for 48 hours.

Next, a pressure-sensitive adhesive solution was prepared by adding 5 parts by weight of a polyisocyanate compound (Coronate L manufactured by Nippon Polyurethane Industry Co., Ltd.) and parts by weight of a photopolymerization initiator (Irgacure 651 manufactured by Ciba Specialty Chemicals Inc.) into 100 parts by weight of the acrylic polymer Y.

A radiation curing-type second pressure-sensitive adhesive layer precursor having a thickness of 30 μm was formed by applying the prepared pressure-sensitive adhesive solution onto the surface of a PET film having a thickness of 50 μm on which a silicone treatment was performed, and heat-crosslinking at 80° C. for 3 minutes.

<Production of the Adhesive Layer>

The same adhesive layer as Example 1 was used as the adhesive layer according to the present example.

<Production of the Film for Manufacturing a Semiconductor Device>

The same product as Example 1 was used as a carrier tape in which the first pressure-sensitive adhesive layer was laminated on the base layer. The second pressure-sensitive adhesive layer that was cut out at 315 mmφ was pasted onto the first pressure-sensitive adhesive layer of this carrier tape at room temperature. After that, the adhesive layer that was cut out at 330 mmφ was pasted at 40° C. so as to entirely cover the second pressure-sensitive adhesive layer precursor. After that, a second pressure-sensitive adhesive layer was formed by irradiating the second pressure-sensitive adhesive layer precursor with ultraviolet rays from the side of the base layer at a cumulative radiation of ultraviolet rays of 300 mJ/cm² using an ultraviolet (UV) irradiation apparatus (UM-810 manufactured by Nitto Seki Co., Ltd). With this, the film for manufacturing a semiconductor device according to the present example was produced.

### Example 10

### <Production of the Second Pressure-Sensitive Adhesive Layer>

The same the second pressure-sensitive adhesive layer as Example 1 was used as the second pressure-sensitive adhesive layer according to the present example.

<Production of the Adhesive Layer>

An adhesive composition solution having a concentration of 23.6% by weight was obtained by dissolving 200 parts by weight of an epoxy resin (EPPN501HY manufactured by Nippon Kayaku Co., Ltd.), 200 parts by weight of a phenol resin (MEH7800 manufactured by Meiwa Plastic Industries, Ltd.), 100 parts by weight of an acrylic copolymer (REBITAL AR31 manufactured by Nogawa Chemical Co., Ltd., weight average molecular weight 700,000, glass transition point −15° C.), and 200 parts by weight of spherical silica (SO-25R manufactured by Admatechs Co., Ltd., average particle size 0.5 μm) as a filler into methylethylketone.

This adhesive composition solution was applied on a release-treated film (peel liner) composed of a 50 μm thick polyethylene terephthalate film subjected to a silicone release treatment and then dried at 130° C. for 2 minutes to produce a 25 μm thick adhesive layer.

<Production of the Film for Manufacturing a Semiconductor Device>

The same product as Example 1 was used as a carrier tape in which the first pressure-sensitive adhesive layer was laminated on the base layer. The second pressure-sensitive adhesive layer that was cut out at 315 mmφ was pasted onto the first pressure-sensitive adhesive layer of this carrier tape at room temperature. After that, a film for manufacturing a semiconductor device according to the present example was produced by pasting an adhesive layer that was cut out at 330 mmφ at 40° C. so as to entirely cover the second pressure-sensitive adhesive layer.

### Example 11

### <Production of the Second Pressure-Sensitive Adhesive Layer>

The same the second pressure-sensitive adhesive layer as Example 8 was used as the second pressure-sensitive adhesive layer according to the present example.

<Production of the Adhesive Layer>

The same adhesive layer as Example 10 was used as the adhesive layer according to the present example.

<Production of the Film for Manufacturing a Semiconductor Device>

The same product as Example 1 was used as a carrier tape in which the first pressure-sensitive adhesive layer was laminated on the base layer. The second pressure-sensitive adhesive layer that was cut out at 315 mmφ was pasted onto the first pressure-sensitive adhesive layer of this carrier tape at room temperature. After that, a film for manufacturing a semiconductor device according to the present example was produced by pasting an adhesive layer that was cut out in 330 mmφ at 40° C. so as to entirely cover the second pressure-sensitive adhesive layer.

### Example 12

<Production of the Second Pressure-Sensitive Adhesive Layer Precursor>

The same second pressure-sensitive adhesive layer precursor as Example 8 was used as the second pressure-sensitive adhesive layer precursor according to the present example.

<Production of the Adhesive Layer>

The same adhesive layer as Example 10 was used as the adhesive layer according to the present example.

<Production of the Film for Manufacturing a Semiconductor Device>

The same product as Example 1 was used as a carrier tape in which the first pressure-sensitive adhesive layer was laminated on the base layer. The second pressure-sensitive adhesive layer that was cut out at 315 mmφ was pasted onto the first pressure-sensitive adhesive layer of this carrier tape at room temperature. After that, the adhesive layer that was cut out at 330 mmφ was pasted at 40° C. so as to entirely cover the second pressure-sensitive adhesive layer precursor. After that, a second pressure-sensitive adhesive layer was formed by irradiating the second pressure-sensitive adhesive layer precursor with ultraviolet rays from the side of the base layer at a cumulative radiation of ultraviolet rays of 300 mJ/cm² using an ultraviolet (UV) irradiation apparatus (UM-810 manufactured by Nitto Seki Co., Ltd). With this, the film for manufacturing a semiconductor device according to the present example was produced.

### Example 13

<Production of the Second Pressure-Sensitive Adhesive Layer Precursor>

The same second pressure-sensitive adhesive layer precursor as Example 9 was used as the second pressure-sensitive adhesive layer precursor according to the present example.

<Production of the Adhesive Layer>

The same adhesive layer as Example 1 was used as the adhesive layer according to the present example.

<Production of the Film for Manufacturing a Semiconductor Device>

The same product as Example 1 was used as a carrier tape in which the first pressure-sensitive adhesive layer was laminated on the base layer. The second pressure-sensitive adhesive layer that was cut out at 315 mmφ was pasted onto the first pressure-sensitive adhesive layer of this carrier tape at room temperature. After that, the adhesive layer that was cut out at 330 mmφ was pasted at 40° C. so as to entirely cover the second pressure-sensitive adhesive layer precursor. After that, a second pressure-sensitive adhesive layer was formed by irradiating the second pressure-sensitive adhesive layer precursor with ultraviolet rays from the side of the base layer at a cumulative radiation of ultraviolet rays of 300 mJ/cm² using an ultraviolet (UV) irradiation apparatus (UM-810 manufactured by Nitto Seki Co., Ltd). With this, the film for manufacturing a semiconductor device according to the present example was produced.

### Example 14

<Production of a Precursor of the Second Pressure-Sensitive Adhesive Layer>

An acrylic polymer X was obtained by placing 80 parts by weight of 2-ethylhexyl acrylate (2EHA), 20 parts by weight of 2-hydroxyethyl acrylate (HEA), and 65 parts by weight of toluene in a reactor equipped with a cooling tube, a nitrogen introducing tube, a thermometer, and a stirring apparatus and polymerizing the mixture at 61° C. in a nitrogen stream for 6 hours.

An acrylic polymer Y was obtained by adding 24.1 parts by weight of 2-methacryloyloxyethyl isocyanate (MOI) (90 mol % to HEA) into 100 parts by weight the acrylic polymer X and performing an addition reaction at 50 C in an air stream for 48 hours.

Next, a pressure-sensitive adhesive solution was prepared by adding 8 parts by weight of a polyisocyanate compound (Coronate L manufactured by Nippon Polyurethane Industry Co., Ltd.) and 5 parts by weight of a photopolymerization initiator (Irgacure 651 manufactured by Ciba Specialty Chemicals Inc.) into 100 parts by weight of the acrylic polymer Y.

A radiation curing-type second pressure-sensitive adhesive layer precursor having a thickness of 30 μm was formed by applying the prepared pressure-sensitive adhesive solution onto the surface of a PET film having a thickness of 50 μm on which a silicone treatment was performed, and heat-crosslinking at 80° C. for 3 minutes.

<Production of the Adhesive Layer>

The same adhesive layer as Example 1 was used as the adhesive layer according to the present example.

<Production of the Film for Manufacturing a Semiconductor Device>

S-400X manufactured by Nitto Denko Co., Ltd. was used as a carrier tape in which a first pressure-sensitive adhesive layer was laminated on a base layer. The second pressure-sensitive adhesive layer precursor that was cut out at 315 mmφ was pasted onto the first pressure-sensitive adhesive layer of this carrier tape at room temperature. Next, a second pressure-sensitive adhesive layer was formed by irradiating the second pressure-sensitive adhesive layer precursor with ultraviolet rays from the side of the base layer at a cumulative radiation of ultraviolet rays of 300 mJ/cm² using an ultraviolet (UV) irradiation apparatus (UM-810 manufactured by Nitto Seki Co., Ltd). After that, a film for manufacturing a semiconductor device according to the present example was produced by pasting the adhesive layer that was cut out at 330 mmφ at 40° C. so as to entirely cover the second pressure-sensitive adhesive layer.

### Comparative Example 1

In the present comparative example, a film for manufacturing a semiconductor device according to the present comparative example was produced in the same manner as Example 1 except that an OPP film (a biaxially stretched polypropylene film, FBS-6 manufactured by Futamura Chemical Co., Ltd.) was used instead of the second pressure-sensitive adhesive layer.

### Comparative Example 2

In the present comparative example, a film for manufacturing a semiconductor device according to the present comparative example was produced in the same manner as Example 1 except that a PE film whose surface was treated by a silicone treatment (a polyethylene film, 40RL-02 manufactured by Oji Specialty Paper Co., Ltd.) was used instead of the second pressure-sensitive adhesive layer. The pasting surface of the PE film to the adhesive layer was the surface in which the silicone treatment was carried out.

### Comparative Example 3

In the present comparative example, a film for manufacturing a semiconductor device according to the present comparative example was produced in the same manner as the Example 1 except that the film for manufacturing a semiconductor device of Example 1 was made to have a structure without the second pressure-sensitive adhesive layer. That is, a film for manufacturing a semiconductor device was produced by pasting only the adhesive layer that was cut out at 330 mmφ at 40° C. without pasting the second pressure-sensitive adhesive layer onto the first pressure-sensitive adhesive layer of a carrier tape.

### Comparative Example 4

### <Production of the Second Pressure-Sensitive Adhesive Layer>

An acrylic polymer X was obtained by placing 80 parts by weight of 2-ethylhexyl acrylate (2EHA), 20 parts by weight of 2-hydroxyethyl acrylate (HEA), and 65 parts by weight of toluene in a reactor equipped with a cooling tube, a nitrogen introducing tube, a thermometer, and a stirring apparatus and polymerizing the mixture at 61° C. in a nitrogen stream for 6 hours.

An acrylic polymer Y was obtained by adding 24.1 parts by weight of 2-methacryloyloxyethyl isocyanate (MCI) (90 mol % to HEA) into 100 parts by weight the acrylic polymer X and performing an addition reaction at 50 C in an air stream for 48 hours.

Next, a pressure-sensitive adhesive solution was prepared by adding 5 parts by weight of a polyisocyanate compound (Coronate L manufactured by Nippon Polyurethane Industry Co., Ltd.) and 5 parts by weight of a photopolymerization initiator (Irgacure 651 manufactured by Ciba Specialty Chemicals Inc.) into 100 parts by weight of the acrylic polymer Y.

A radiation curing-type second pressure-sensitive adhesive layer having a thickness of 30 μm was formed by applying the prepared pressure-sensitive adhesive solution onto the surface of a PET film having a thickness of 50 μm on which a silicone treatment was performed and heat-crosslinking at 80° C. for 3 minutes.

<Production of the Adhesive Layer>

The same adhesive layer as Example 9 was used as the adhesive layer according to the present comparative example.

<Production of the Film for Manufacturing a Semiconductor Device>

The same product as Example 1 was used as a carrier tape in which the first pressure-sensitive adhesive layer was laminated on the base layer. The second pressure-sensitive adhesive layer that was cut out at 315 mmφ was pasted onto the first pressure-sensitive adhesive layer of this carrier tape at room temperature. After that, a film for manufacturing a semiconductor device according to the present comparative example was produced by pasting an adhesive layer that was cut out in 330 mmφ at 40° C. so as to entirely cover the second pressure-sensitive adhesive layer.

### Comparative Example 5

In the present comparative example, a film for manufacturing a semiconductor device according to the present comparative example was produced in the same manner as Comparative Example 4 except that GE-300 manufactured by Nitto Denko Co., Ltd. was used as a carrier tape in which the first pressure-sensitive adhesive layer was laminated on the base layer.

### Comparative Example 6

In the present comparative example, a film for manufacturing a semiconductor device according to the present comparative example was produced in the same manner as comparative example 4 except that BT-315S manufactured by Nitto Denko Co., Ltd. was used as a carrier tape in which the first pressure-sensitive adhesive layer was laminated on the base layer.

(Peeling Strength Between the Second Pressure-Sensitive Adhesive Layer and the Adhesive Layer)

A sample 100 mm long×20 mm wide was cut out from each of the films for manufacturing a semiconductor device that were produced in the Examples and Comparative Examples. Next, the adhesive layer was reinforced by pasting a tape (BT-315 manufactured by Nitto Denko Co., Ltd.) to the surface of the adhesive layer at room temperature. Further, the peeling strength between the second pressure-sensitive adhesive layer and the adhesive layer was measured by chucking both layers and using a tensile tester (AGS-J manufactured by Shimadzu Corporation). The peeling was performed under conditions of a peeling speed of 300 mm/min, a temperature of 25° C., and a relative humidity of 50% Rh.

(Peeling Power Between the First Pressure-Sensitive Adhesive Layer and the Second Pressure-Sensitive Adhesive Layer)

The adhesive layer was peeled from each of the films for manufacturing a semiconductor device that were produced in the Examples and Comparative Examples. Subsequently, a sample 100 mm long×20 mm wide was cut out from each of the films for manufacturing a semiconductor device after the adhesive layer was peeled. Then, the second pressure-sensitive adhesive layer was reinforced by pasting a tape (BT-315 manufactured by Nitto Denko Co., Ltd.) to the surface of the second pressure-sensitive adhesive at room temperature. Further, the peeling strength between the second pressure-sensitive adhesive layer and the first pressure-sensitive adhesive layer was measured by chucking the both layers and using a tensile tester (AGS-J manufactured by Shimadzu Corporation). The peeling was performed under conditions of a peeling speed of 300 mm/min, a temperature of 25° C., and a relative humidity of 50% Rh.

(Peeling Power Between the First Pressure-Sensitive Adhesive Layer and the SUS)

The adhesive layer and the second pressure-sensitive adhesive layer were peeled from each of the films for manufacturing a semiconductor device that were produced in the Examples and Comparative Examples. Subsequently, a sample 100 mm long×20 mm wide was cut out from each of the films for manufacturing a semiconductor device after the adhesive layer and the second pressure-sensitive adhesive layer were peeled. Next, a SUS-304BA plate was pasted to the surface of the first pressure sensitive adhesive layer using a 2 kg roller. After that, the peeling strength between the first pressure-sensitive adhesive layer and the SUS304-BA plate was measured by chucking both layers and using a tensile tester (AGS-J manufactured by Shimadzu Corporation). The peeling was performed under conditions of a peeling speed of 300 mm/min, a temperature of 25° C., and a relative humidity of 50% Rh.

(Ring Pasting Property)

A dicing ring pasting property was evaluated with the following points using each of the films for manufacturing a semiconductor device of the Examples and Comparative Examples.

The separator was peeled from the film for manufacturing a semiconductor device, and then the dicing ring was pasted onto the first pressure-sensitive adhesive layer by roll pressing at 25° C. In this case, the ring pasting property was evaluated by marking the case where the pasting was performed without wrinkles “◯”, and marking the case where wrinkles were generated “X”. The result is shown in Tables 1 to 3.

(Reworking Property)

A reworking property was evaluated with the following points using each of the films for manufacturing a semiconductor device of the Examples and Comparative Examples.

The separator was peeled from the film for manufacturing a semiconductor device, and then the dicing ring was pasted onto the first pressure-sensitive adhesive layer by roll pressing at 25° C. The reworking property was evaluated by peeling the film for manufacturing a semiconductor device from the ring where the film for manufacturing a semiconductor device was pasted, marking the case where the residue (adhesive residue) of the first pressure-sensitive adhesive layer to the ring was not confirmed “◯”, and marking the case where it was confirmed “X”. The result is shown in Tables 1 to 3.

(Measurement of the Glass Transition Point (Tg))

The glass transition point of each of the acylic copolymers that were used in the Examples and Comparative Examples was measured from Tan (G″(loss modulus)/G′(storage modulus)) at a rate of temperature rise of 10° C./min and a frequency of 1 MHz using a viscoelasticity measurement apparatus (ARES manufactured by Rheometic Scientific, Inc).

(Wafer Pasting Property, Chip Fly, Chip Contamination Property, and Pickup Property)

A wafer pasting property, chip fly, a chip contamination property, and a pickup property were evaluated with the following points using each of the films for manufacturing a semiconductor device of the Examples and Comparative Examples by performing steps from the step of polishing the backside of the semiconductor wafer to the pickup step.

Backside polishing was performed on a semiconductor wafer (12 inch diameter, 0.6 mm thick), and a mirror wafer having a thickness of 0.05 mm was used as a work piece. The separator was peeled from the film for manufacturing a semiconductor device, and then the mirror wafer was pasted onto the adhesive layer by roll pressing at 40° C. The wafer pasting property was evaluated by marking the case where the pasting was performed without wrinkles “◯”, and marking the case where wrinkles were generated “X”. The result is shown in Tables 1 to 3. Further, dicing was performed, and 20 semiconductor chips were formed. The dicing was performed in full cut so that the chip size became 10 mm square. In the dicing, a dicing blade Z1 described below was used up to half the thickness of the semiconductor wafer. A dicing blade Z2 described below was used up to half the thickness of the second pressure-sensitive adhesive layer. The dicing condition was changed as follows depending on the type of the dicing blades Z1 and Z2. Chip fly was evaluated by marking the case where chip fly of the semiconductor chip was generated during dicing “X” and marking the case where the chip fly was not generated “◯”. The result is shown in Tables 1 to 3.

<Wafer Grinding Condition>

Grinding apparatus: DFG-8560 manufactured by DISCO Corporation

Semiconductor wafer: 12 inch diameter (the backside was polished from 0.6 mm to 0.05 mm thick.)

<Wafer Pasting Condition>

Pasting apparatus: MA-3000II manufactured by Nitto Seiki Co., Ltd.

Pasting speed meter: 10 mm/min

Pasting pressure: 0.15 MPa

Stage temperature during pasting: 40° C.

<Dicing Condition>

Dicing apparatus: DFD-6361 manufactured by DISCO Corporation

Dicing ring: 2-12-1 manufactured by DISCO Corporation

Dicing speed: 30 mm/sec

Dicing blade:
Z1; NBC-ZH2030-SE27HCDD manufactured by DISCO Corporation
Dicing blade rotation: 40,000 rpm
Blade height: half the thickness of the semiconductor wafer
Z2; NBC-ZH1030-SE27HCBB manufactured by DISCO Corporation
Dicing blade rotation: 45,000 rpm
Blade height: half the thickness of the second pressure-sensitive adhesive layer

Cut method: A mode/step cut

Wafer chip size: 10.0 mm square

Next, an expanding step was performed to make a space between chips a prescribed size by stretching the film for manufacturing a semiconductor device. The pickup property was evaluated by picking up the semiconductor chip with a method of pushing up from the side of the base layer of each of the films for manufacturing a semiconductor device with needles. Specifically, 20 semiconductor chips were continuously picked up, and each semiconductor chip was observed with a microscope. The pickup conditions were as follows. As the result of observation, the chip contamination property was evaluated by marking the case where the number of burrs and whiskers attached to the side surface of the semiconductor chip was zero “◯”, marking the case where the number of burrs and whiskers was 1 to 10 “Δ”, and marking the case where the number of burrs and whiskers was 11 or more “X”. The pickup property was evaluated by performing the pickup of the semiconductor chip in which the pickup height was in a range of 0 to 600 μm, marking the case where all of the semiconductor chips were picked up “◯”, and marking the case where any were not picked up “X”. The result is shown in Tables 1 to 3.

<Pickup Conditions>

Pickup apparatus: SPA-300 manufactured by Shinkawa Ltd.

Number of needles: 5 needles

Type of the needles: diameter 0.7 mm, acute angle 15°, length 10 mm, and tip R 350 μm

Pickup time: 1000 msec

Pickup speed: 5 mm/sec

Pickup height: same as above

(Measurement of Bending Stiffness)

The thickness of a film (a dicing film) in which a base layer, a first pressure-sensitive adhesive, and a second pressure-sensitive adhesive layer were sequentially laminated was measured. After that, it was cutout into a 10 mm wide strip, and a value of the tensile storage modulus (E [unit: Pa]) at 25° C. was recorded by measuring the tensile storage modulus at a rate of temperature rise of 5° C./min using a dynamic viscoelasticity measurement apparatus (RSA-III manufactured by Rheometric Scientific, Inc). Then the bending stiffness S calculated by E×I was obtained. Here, I is a second moment of area represented with b×T³/12, b is 10 (mm) that is the width of a test piece of the dicing film, T is the thickness (mm) of the dicing film, and E is the tensile storage modulus (Pa) at 25° C. of the dicing film. The result is shown in Tables 1 to 3.

(Overall Determination)

The evaluation was performed by marking the case where even one X exists in the evaluation results of the ring pasting property, the wafer pasting property, the chip contamination property, the chip fly, the pickup property, and the rework property “X”, and by marking the case where all evaluation results were ◯“◯”. The result is shown in Tables 1 to 3.

TABLE 1

| | Example 1 | Example 2 | Example 3 | Example 4 | Example 5 | Example 6 | Example 7 |
|---|---|---|---|---|---|---|---|
| PEELING STRENGTH (X) OF SECOND | 0.08 | 0.08 | 0.08 | 0.08 | 0.08 | 0.08 | 0.08 |
| PRESSURE-SENSITIVE ADHESIVE | | | | | | | |
| LAYER AND ADHESIVE LAYER | | | | | | | |
| [N/20 mm] | | | | | | | |
| PEELING STRENGTH (Y) OF FIRST | 1.18 | 0.65 | 0.72 | 0.31 | 0.25 | 0.68 | 0.24 |
| PRESSURE-SENSITIVE ADHESIVE | | | | | | | |
| LAYER AND SECOND | | | | | | | |
| PRESSURE-SENSITIVE ADHESIVE | | | | | | | |
| LAYER [N/20 mm] | | | | | | | |
| RATIO OF Y TO X (Y/X) | 14.8 | 8.1 | 9.0 | 3.9 | 3.1 | 8.5 | 3.0 |
| PEELING STRENGTH OF FIRST | 5.2 | 3.8 | 4.7 | 2.3 | 1.1 | 10.8 | 2.2 |
| PRESSURE-SENSITIVE ADHESIVE | | | | | | | |
| LAYER AND SUS [N/20 mm] | | | | | | | |
| BENDING STIFFNESS | 1.7 × 10⁵ | 1.5 × 10⁵ | 6.0 × 10⁵ | 6.1 × 10⁴ | 2.2 × 10⁵ | 6.7 × 10⁵ | 2.4 × 10⁵ |
| RING PASTING PROPERTY | ◯ | ◯ | ◯ | ◯ | ◯ | ◯ | ◯ |
| WAFER PASTING PROPERTY | ◯ | ◯ | ◯ | ◯ | ◯ | ◯ | ◯ |
| CHIP CONTAMINATION PROPERTY | ◯ | ◯ | ◯ | ◯ | ◯ | ◯ | ◯ |
| PRESENCE OF CHIP FLY | ◯ | ◯ | ◯ | ◯ | ◯ | ◯ | ◯ |
| PICKUP PROPERTY | ◯ | ◯ | ◯ | ◯ | ◯ | ◯ | ◯ |
| REWORKING PROPERTY | ◯ | ◯ | ◯ | ◯ | ◯ | ◯ | ◯ |
| OVERALL DETERMINATION | ◯ | ◯ | ◯ | ◯ | ◯ | ◯ | ◯ |

TABLE 2

| | Example 8 | Example 9 | Example 10 | Example 11 | Example 12 | Example 13 | Example 14 |
|---|---|---|---|---|---|---|---|
| PEELING STRENGTH (X) OF SECOND | 0.015 | 0.12 | 0.10 | 0.05 | 0.18 | 0.08 | 0.015 |
| PRESSURE-SENSITIVE ADHESIVE | | | | | | | |
| LAYER AND ADHESIVE LAYER | | | | | | | |
| [N/20 mm] | | | | | | | |
| PEELING STRENGTH (Y) OF FIRST | 0.69 | 6.77 | 1.18 | 0.87 | 6.77 | 6.77 | 5.98 |
| PRESSURE-SENSITIVE ADHESIVE | | | | | | | |
| LAYER AND SECOND | | | | | | | |
| PRESSURE-SENSITIVE ADHESIVE | | | | | | | |
| LAYER [N/20 mm] | | | | | | | |
| RATIO OF Y TO X (Y/X) | 46.0 | 56.4 | 11.8 | 17.4 | 37.6 | 84.6 | 398.7 |
| PEELING STRENGTH OF FIRST | 5.2 | 5.2 | 5.2 | 5.2 | 5.2 | 5.2 | 5.2 |
| PRESSURE-SENSITIVE ADHESIVE | | | | | | | |
| LAYER AND SUS [N/20 mm] | | | | | | | |
| BENDING STIFFNESS | 2.1 × 10⁵ | 1.5 × 10⁵ | 1.7 × 10⁵ | 2.1 × 10⁵ | 1.7 × 10⁵ | 1.7 × 10⁵ | 2.1 × 10⁵ |
| RING PASTING PROPERTY | ◯ | ◯ | ◯ | ◯ | ◯ | ◯ | ◯ |
| WAFER PASTING PROPERTY | ◯ | ◯ | ◯ | ◯ | ◯ | ◯ | ◯ |
| CHIP CONTAMINATION PROPERTY | ◯ | ◯ | ◯ | ◯ | ◯ | ◯ | ◯ |
| PRESENCE OF CHIP FLY | ◯ | ◯ | ◯ | ◯ | ◯ | ◯ | ◯ |
| PICKUP PROPERTY | ◯ | ◯ | ◯ | ◯ | ◯ | ◯ | ◯ |
| REWORKING PROPERTY | ◯ | ◯ | ◯ | ◯ | ◯ | ◯ | ◯ |
| OVERALL DETERMINATION | ◯ | ◯ | ◯ | ◯ | ◯ | ◯ | ◯ |

TABLE 3

| | Comparative | Comparative | Comparative | Comparative | Comparative | Comparative |
|---|---|---|---|---|---|---|
| | Example 1 | Example 2 | Example 3 | Example 4 | Example 5 | Example 6 |
| PEELING STRENGTH (X) OF SECOND | 0.66 | 0.008 | — | 0.35 | 0.35 | 0.35 |
| PRESSURE-SENSITIVE ADHESIVE | | | | | | |
| LAYER AND ADHESIVE LAYER | | | | | | |
| [N/20 mm] | | | | | | |
| PEELING STRENGTH (Y) OF FIRST | 4.88 | 5.34 | — | 10.05 | 4.5 | 15.8 |
| PRESSURE-SENSITIVE ADHESIVE | | | | | | |
| LAYER AND SECOND | | | | | | |
| PRESSURE-SENSITIVE ADHESIVE | | | | | | |
| LAYER [N/20 mm] | | | | | | |
| RATIO OF Y TO X (Y/X) | 7.4 | 667.5 | — | 28.7 | 12.86 | 45.14 |
| PEELING STRENGTH OF FIRST | 5.2 | 5.2 | 5.2 | 5.2 | 0.02 | 13 |
| PRESSURE-SENSITIVE ADHESIVE | | | | | | |
| LAYER AND SUS [N/20 mm] | | | | | | |
| BENDING STIFFNESS | 4.1 × 10⁵ | 3.1 × 10⁵ | 6.3 × 10⁴ | 1.8 × 10⁵ | 3.1 × 10⁴ | 1.3 × 10⁶ |
| RING PASTING PROPERTY | ◯ | ◯ | ◯ | ◯ | X | ◯ |
| WAFER PASTING PROPERTY | ◯ | ◯ | ◯ | ◯ | X | ◯ |
| CHIP CONTAMINATION PROPERTY | Δ | X | ◯ | ◯ | ◯ | ◯ |
| PRESENCE OF CHIP FLY | ◯ | X | ◯ | ◯ | ◯ | ◯ |
| PICKUP PROPERTY | X | ◯ | X | X | ◯ | X |
| REWORKING PROPERTY | ◯ | ◯ | ◯ | ◯ | ◯ | X |
| OVERALL DETERMINATION | X | X | X | X | X | X |

(Result)

As seen in Tables 1 and 2, the chip fly of a thin semiconductor chip having a large surface area was prevented during dicing when using the films for manufacturing a semiconductor device according to Examples 1 to 14 having a structure in which the first pressure-sensitive adhesive layer and the second pressure-sensitive adhesive layer are sequentially laminated on the base layer. Further, there were no burrs and whiskers attached to the side surface, etc. of the semiconductor chip, and contamination of the semiconductor chip was prevented. Furthermore, all semiconductor chips were picked up well when picking up the semiconductor chips, and an excellent peeling property was also confirmed.

On the other hand, when the OPP film was used instead of the second pressure-sensitive adhesive layer as with the film for manufacturing a semiconductor device according to Comparative Example 1, it was confirmed that the cutting debris resulting from the OPP film attached to the side surface, etc. of the semiconductor chip as burrs and whiskers because the dicing blade cut into apart of the OPP film also during dicing. Further, the pickup failure of the semiconductor chip occurred because of a poor peeling property with the adhesive layer. Further, when the PE film whose surface was treated by a silicone treatment was used instead of the second pressure-sensitive adhesive layer as with the film for manufacturing a semiconductor device according to Comparative Example 2, it was confirmed that the cut debris resulting from the PE film attach to the side surface, etc. of the semiconductor chip as burrs and whiskers because the dicing blade cut into a part of the PE film also during dicing. When the irradiation of an ultraviolet ray was not performed to the second pressure-sensitive adhesive layer as with the film for manufacturing a semiconductor device according to Comparative Example 4, the second pressure-sensitive adhesive was not cured, the peeling property with the adhesive layer was extremely decreased, and pickup failure of the semiconductor chip occurred. Further, when the bending stiffness was small as with the film for manufacturing a semiconductor device according to Comparative Example 5, the film was poor because wrinkles were generated during pasting of the wafer. Furthermore, when the bending stiffness was large as with the film for manufacturing a semiconductor device according to Comparative Example 6, the film was poor because the film did not bend during pickup and the peeling between the adhesive layer and the second pressure-sensitive adhesive layer did not start.

1. A film for manufacturing a semiconductor device used when manufacturing a semiconductor device, comprising:
a base layer;
a first pressure-sensitive adhesive layer provided on the base layer;
a radiation curing-type second pressure-sensitive adhesive layer that is provided on the first pressure-sensitive adhesive layer and that is cured by radiation irradiation in advance; and
an adhesive layer provided on the second pressure-sensitive adhesive layer.

2. The film for manufacturing a semiconductor device according to claim 1, wherein the second pressure-sensitive adhesive layer and the adhesive layer are provided so as to fit at least inside of a pasting portion of the dicing ring in the first pressure-sensitive adhesive layer,
the plane shape of the adhesive layer is larger than that of the second pressure-sensitive adhesive layer, and the adhesive layer is provided so as to cover the entire surface of the second pressure-sensitive adhesive layer, and
the peripheral edge part in the adhesive layer that is not located on the second pressure-sensitive adhesive layer is provided on the first pressure-sensitive adhesive layer.

3. The film for manufacturing a semiconductor device according to claim 1, wherein bending stiffness S of a structure in which the base layer, the first pressure-sensitive adhesive layer, and the second pressure-sensitive adhesive layer are laminated is in a range of 5.0×10⁴ to 7.0×10⁵,
wherein S=E×I, and I is a second moment of area represented with b×T³/12, b is 10 (mm) that is the width of a test piece of the structure, T is a thickness (mm) of the structure, and E is a tensile storage modulus (Pa) at 25° C. of the structure.

4. The film for manufacturing a semiconductor device according to claim 1, wherein peeling strength X between the second pressure-sensitive adhesive layer and the adhesive layer is in a range of 0.01 to 0.2 N/20 mm.

5. The film for manufacturing a semiconductor device according to claim 1, wherein peeling strength Y between the first pressure-sensitive adhesive layer and the second pressure-sensitive adhesive layer is in a range of 0.2 to 10 N/20 mm.

6. The film for manufacturing a semiconductor device according to claim 1, wherein the ratio (Y/X) of the peeling strength Y between the first pressure-sensitive adhesive layer and the second pressure-sensitive adhesive layer to the peeling strength X between the second pressure-sensitive adhesive layer and the adhesive layer is in a range of 3 to 500.

7. The film for manufacturing a semiconductor device according to claim 1, wherein the thickness of the second pressure-sensitive adhesive layer is in a range of 10 to 100 μm.

8. The film for manufacturing a semiconductor device according to claim 2, wherein the peeling strength between the first pressure-sensitive adhesive layer and a SUS304-BA plate is in a range of 0.2 to 11 N/20 mm.

9. The film for manufacturing a semiconductor device according to claim 1, wherein the second pressure-sensitive adhesive layer is formed on the first pressure-sensitive adhesive layer after a precursor of the second pressure-sensitive adhesive layer is cured by radiation irradiation.

10. The film for manufacturing a semiconductor device according to claim 1, wherein the second pressure-sensitive adhesive layer is formed by being cured by radiation irradiation after a precursor of the second pressure-sensitive adhesive layer is provided on the first pressure-sensitive adhesive layer.

11. The film for manufacturing a semiconductor device according to claim 1, wherein the adhesive layer is formed on the second pressure-sensitive adhesive layer that is cured by radiation irradiation in advance.

12. The film for manufacturing a semiconductor device according to claim 1, wherein the adhesive layer is formed on the precursor of the second pressure-sensitive adhesive layer before being cured by radiation irradiation.

13. The film for manufacturing a semiconductor device according to claim 1, wherein the adhesive layer is formed of at least an epoxy resin, a phenol resin, and an acrylic resin.

14. The film for manufacturing a semiconductor device according to claim 13, wherein the glass transition temperature of the acrylic resin is in a range of −30 to 10° C.

15. The film for manufacturing a semiconductor device according to claim 1, wherein the second pressure-sensitive adhesive layer is formed of at least an acrylic polymer.

16. A method of manufacturing a semiconductor device using the film for manufacturing a semiconductor device according to claim 1, comprising:
adhering a semiconductor wafer onto the adhesive layer of the film for manufacturing a semiconductor device by pressing;
forming a semiconductor chip by dicing the semiconductor wafer together with the adhesive layer, in which the cut depth of dicing is stopped at the second pressure-sensitive adhesive layer; and
peeling the semiconductor chip from the second pressure-sensitive adhesive layer together with the adhesive layer, wherein
the second pressure-sensitive adhesive layer is not irradiated with radiation from the step of adhering a semiconductor wafer by pressing to the step of peeling a semiconductor chip.

17. The film for manufacturing a semiconductor device according to claim 1, further comprising a separator provided on the adhesive layer.

18. The film for manufacturing a semiconductor device according to claim 15, wherein the acrylic polymer comprises 50% by weight or more alkylacrylate monomer having the formula CH₂═CHCOOR, wherein R represents an alkyl group having 6 to 10 carbon atoms.
